(19) United States
(12) Patent Application Publication
(10) Pub. No.: US 2023/0402821 A1
(43) Pub. Date: Dec. 14, 2023

(54) NITRIDE SEMICONDUCTOR LIGHT-EMITTING ELEMENT

(71) Applicant: Nuvoton Technology Corporation Japan, Kyoto (JP)

(72) Inventors: Toru TAKAYAMA, Toyama (JP); Shinji YOSHIDA, Shiga (JP)

(21) Appl. No.: 18/447,126

(22) Filed: Aug. 9, 2023

Related U.S. Application Data
(63) Continuation-in-part of application No. PCT/JP2022/011389, filed on Mar. 14, 2022.

(30) Foreign Application Priority Data
Mar. 24, 2021 (JP) 2021-050352

(51) Int. Cl. H01S 5/30; H01S 5/32; H01S 5/34; H01S 5/343; H01S 5/042

(52) U.S. Cl. CPC H01S 5/3013; H01S 5/3211; H01S 5/3407; H01S 5/34346; H01S 5/04252

(57) ABSTRACT

A nitride semiconductor light-emitting element includes: an N-type cladding layer; an N-side first guide layer; an N-side second guide layer; an active layer including a well layer and a barrier layer; and a P-type cladding layer. The band gap energy of the barrier layer is larger than the band gap energy of the N-side second guide layer. The band gap energy of the N-side second guide layer is smaller than the band gap energy of the N-side first guide layer. The band gap energy of the N-side first guide layer is smaller than the band gap energy of the N-type cladding layer. The cladding layers, the guide layers, and the barrier layer each comprise a nitride semiconductor including Al.

### CROSS REFERENCE TO RELATED APPLICATIONS

This is a continuation-in-part application of PCT International Application No. PCT/JP2022/011389 filed on Mar. 14, 2022, designating the United States of America, which is based on and claims priority of Japanese Patent Application No. 2021-050352 filed on Mar. 24, 2021. The entire disclosures of the above-identified applications, including the specifications, drawings and claims are incorporated herein by reference in their entirety.

### FIELD

The present disclosure relates to nitride semiconductor light-emitting elements.

### BACKGROUND

Conventionally, nitride semiconductor light-emitting elements that emit blue light have been known, but there is a demand for high-power nitride semiconductor light-emitting elements that emit ultraviolet light having a shorter wavelength (see PTL 1, for example). If a watt-class ultraviolet laser light source is achievable by a nitride semiconductor light-emitting element, for example, a nitride semiconductor light-emitting element can be used in, for instance, a light source for exposure or a light source for processing.

### CITATION LIST

### Patent Literature

### PTL 1: Japanese Unexamined Patent Application Publication No. 2014-131019

### SUMMARY

### Technical Problem

In a nitride semiconductor light-emitting element that emits ultraviolet light, an active layer having a quantum well structure including an AlGaN layer as a barrier layer is used, for example. To emit ultraviolet light, the band gap energy of the barrier layer needs to be increased. If the Al composition ratio of the barrier layer is increased to increase the band gap energy of the barrier layer, the refractive index of the barrier layer decreases. For this reason, the refractive index of a cladding layer, which is for confining ultraviolet light to the active layer, needs to be sufficiently lower than the refractive index of the barrier layer. When using an AlGaN layer as the cladding layer, it is necessary to increase the Al composition ratio of the cladding layer to lower the refractive index of the cladding layer. When such a cladding layer made of AlGaN having a high Al composition ratio crystal grows on a substrate made of, for example, GaN, a tensile strain on the substrate from the cladding layer increases. Therefore, when the cladding layer, the active layer, and so on crystal grow on a wafer made of GaN to manufacture the nitride semiconductor light-emitting element, the wafer cracks easily due to the tensile strain caused by the AlGaN layers. To inhibit such cracks in the wafer, reducing the thickness of the cladding layer made of AlGaN to reduce the strain on the substrate from the cladding layer is a conceivable solution. Since electrical resistance increases in a P-type cladding layer made of P-type AlGaN having a high Al composition ratio, the thickness of the P-type cladding layer is set much thinner than the thickness of an N-type cladding layer, and the impurity concentration of the P-type cladding layer is set higher than the impurity concentration of the N-type cladding layer. The refractive index of such a P-type cladding layer is higher than the refractive index of the N-type cladding layer. There is therefore more light on the P-type cladding layer side than the active layer side. This reduces the optical confinement factor of the active layer, and this in turn reduces the thermal saturation level of light output. It is therefore difficult to achieve high-output nitride semiconductor light-emitting elements.

The present disclosure is conceived to overcome the problems described above and has an object to provide a nitride semiconductor light-emitting element with a reduced strain on the semiconductor stack and an increased optical confinement factor of the active layer.

### Solution to Problem

To overcome the above-described problems, a nitride semiconductor light-emitting element according to one aspect of the present disclosure includes: an N-type cladding layer; an N-side first guide layer disposed above the N-type cladding layer; an N-side second guide layer disposed above the N-side first guide layer; an active layer disposed above the N-side second guide layer and including a well layer and a barrier layer; and a P-type cladding layer disposed above the active layer. The band gap energy of the barrier layer is larger than the band gap energy of the N-side second guide layer. The band gap energy of the N-side second guide layer is smaller than the band gap energy of the N-side first guide layer. The band gap energy of the N-side first guide layer is smaller than the band gap energy of the N-type cladding layer. The N-type cladding layer, the N-side first guide layer, the N-side second guide layer, the barrier layer, and the P-type cladding layer each comprise a nitride semiconductor including Al.

A nitride semiconductor light-emitting element according to another aspect of the present disclosure includes: an N-type cladding layer; an N-side guide layer disposed above the N-type cladding layer; an active layer disposed above the N-side guide layer and including a well layer and a barrier layer; a P-type cladding layer disposed above the active layer; a P-side first guide layer disposed between the active layer and the P-type cladding layer; and an electron barrier layer disposed between the P-side first guide layer and the P-type cladding layer. The band gap energy of the barrier layer is larger than the average band gap energy of the N-side guide layer. The band gap energy of the N-type cladding layer is larger than the average band gap energy of the N-side guide layer. The band gap energy of the N-side guide layer is larger in the lower end portion of the N-side guide layer than in the upper end portion of the N-side guide layer. The band gap energy of the P-type cladding layer is larger than the band gap energy of the P-side first guide layer. The band gap energy of the P-side first guide layer is larger than the average band gap energy of the N-side guide layer. The N-type cladding layer, the N-side guide layer, the barrier layer, the P-type cladding layer, the P-side first guide layer, and the electron barrier layer each comprise a nitride semiconductor including Al.

### Advantageous Effects

The present disclosure can provide a nitride semiconductor light-emitting element with a reduced strain on the semiconductor stack and an increased optical confinement factor of the active layer.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a schematic plan view of the overall configuration of a nitride semiconductor light-emitting element according to Embodiment 1.

FIG. 2A is a schematic cross-sectional view of the overall configuration of the nitride semiconductor light-emitting element according to Embodiment 1.

FIG. 2B is a schematic cross-sectional view of the configuration of the active layer included in the nitride semiconductor light-emitting element according to Embodiment 1.

FIG. 3 is a schematic diagram outlining the light intensity distribution in the stacking direction of the nitride semiconductor light-emitting element according to Embodiment 1.

FIG. 4 is a graph showing coordinates of positions in the stacking direction of the nitride semiconductor light-emitting element according to Embodiment 1.

FIG. 5 is a graph schematically showing the band gap energy distribution and the light intensity distribution in the stacking direction of a semiconductor stack according to Comparative Example 1.

FIG. 6 is a graph schematically showing the band gap energy distribution and the light intensity distribution in the stacking direction of a semiconductor stack according to Embodiment 1.

FIG. 7 is a graph schematically showing the band gap energy distribution and the light intensity distribution of a semiconductor stack according to a variation of Embodiment 1.

FIG. 8 is a graph showing the refractive index distribution and the light intensity distribution of a semiconductor stack according to Comparative Example 2.

FIG. 9 is a graph showing the refractive index distribution and the light intensity distribution of the semiconductor stack according to Embodiment 1.

FIG. 10 is a table showing the relationship between the composition of the Al composition ratio of each guide layer and properties of a nitride semiconductor light-emitting element.

FIG. 11 is a graph showing the relationship between the electron wave function and the conduction band potential energy distribution in the vicinity of the active layer when the Al composition ratio of each barrier layer is 0.02.

FIG. 12 is a graph showing the relationship between the electron wave function and the conduction band potential energy distribution in the vicinity of the active layer when the Al composition ratio of each barrier layer is 0.05.

FIG. 13 is a graph showing the relationship between the Al composition ratio of each barrier layer and a band offset ΔEc.

FIG. 14 is a graph showing the relationship between the thickness of the N-type cladding layer in the nitride semiconductor light-emitting element according to Embodiment 1 and waveguide loss.

FIG. 15 is a graph showing the relationship between the thickness of the N-type cladding layer in the nitride semiconductor light-emitting element according to Embodiment 1 and the optical confinement factor.

FIG. 16 is a schematic lateral view of bow of the semiconductor stack and the base material of a substrate according to Embodiment 1 which occurs when the semiconductor stack is stacked on the base material.

FIG. 17 is a graph showing the amount of bow of the semiconductor stack and the base material of the substrate according to Embodiment 1 which occurs when the semiconductor stack is stacked on the base material.

FIG. 18 is a first graph showing the relationship between each guide layer according to Embodiment 1 and waveguide loss calculated through a simulation.

FIG. 19 is a second graph showing the relationship between each guide layer according to Embodiment 1 and waveguide loss calculated through the simulation.

FIG. 20 is a third graph showing the relationship between each guide layer according to Embodiment 1 and waveguide loss calculated through the simulation.

FIG. 21A is a schematic cross-sectional view of the overall configuration of a nitride semiconductor light-emitting element according to Embodiment 2.

FIG. 21B is a schematic cross-sectional view of the configuration of the active layer included in the nitride semiconductor light-emitting element according to Embodiment 2.

FIG. 22 is a graph schematically showing the band gap energy distribution and the light intensity distribution in the stacking direction of a semiconductor stack according to Embodiment 2.

FIG. 23 is a schematic cross-sectional view of the overall configuration of a nitride semiconductor light-emitting element according to Embodiment 3.

FIG. 24 is a schematic cross-sectional view of the overall configuration of a nitride semiconductor light-emitting element according to Embodiment 4.

FIG. 25 is a schematic cross-sectional view of the overall configuration of a nitride semiconductor light-emitting element according to Embodiment 5.

FIG. 26 is a schematic cross-sectional view of the overall configuration of a nitride semiconductor light-emitting element according to Variation 1 of Embodiment 5.

FIG. 27 is a schematic cross-sectional view of the overall configuration of a nitride semiconductor light-emitting element according to Variation 2 of Embodiment 5.

FIG. 28 is a schematic cross-sectional view of the overall configuration of a nitride semiconductor light-emitting element according to Variation 3 of Embodiment 5.

FIG. 29 is a schematic cross-sectional view of the overall configuration of a nitride semiconductor light-emitting element according to Embodiment 6.

FIG. 30 is a schematic cross-sectional view of the overall configuration of a nitride semiconductor light-emitting element according to Embodiment 7.

FIG. 31 is a schematic cross-sectional view of the overall configuration of a nitride semiconductor light-emitting element according to Embodiment 8.

FIG. 32 is a schematic cross-sectional view of the overall configuration of a nitride semiconductor light-emitting element according to Embodiment 9.

### DESCRIPTION OF EMBODIMENTS

Hereinafter, embodiments of the present disclosure will be described in detail with reference to the drawings. Note that each of the embodiments described below shows a specific example of the present disclosure. Therefore, numerical values, shapes, materials, elements, the arrangement and connection of the elements, etc., indicated in the following embodiments are mere examples, and are not intended to limit the present disclosure.

The figures are schematic diagrams and are not necessarily precise illustrations. Accordingly, the figures are not necessarily to scale. Substantially identical elements in the drawings are assigned with like reference signs, and redundant description is omitted or simplified.

In the present Specification, the terms “above” and “below” do not refer to the upward (vertically upward) direction and downward (vertically downward) direction in terms of absolute spatial recognition, but are used as terms defined by relative positional relationships based on the stacking order of the stacked configuration. The terms “above” and “below” are applied not only when two elements are disposed with a gap therebetween and a separate element is interposed between the two elements, but also when two elements are disposed in contact with each other.

### Embodiment 1

A nitride semiconductor light-emitting element according to Embodiment 1 will be described.

### [1-1. Overall Configuration]

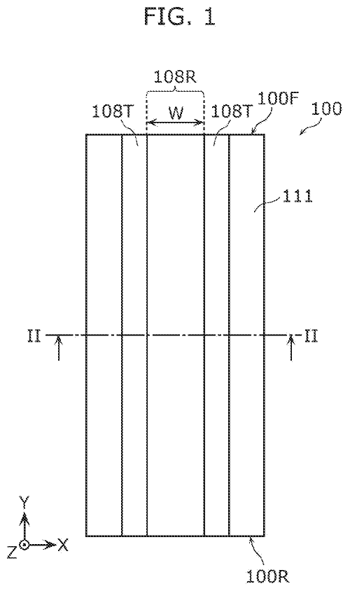

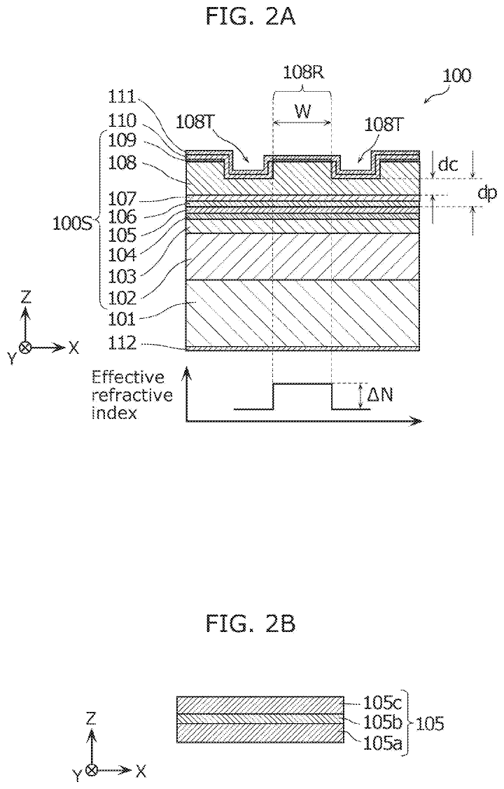

First, the overall configuration of the nitride semiconductor light-emitting element according to the present embodiment will be described with reference to FIG. 1, FIG. 2A, and FIG. 2B. FIG. 1 and FIG. 2A are a schematic plan view and a schematic cross-sectional view, respectively, of the overall configuration of nitride semiconductor light-emitting element 100 according to the present embodiment. FIG. 2A illustrates a cross section taken at line II-II in FIG. 1. FIG. 2B is a schematic cross-sectional view of the configuration of active layer 105 included in nitride semiconductor light-emitting element 100 according to the present embodiment. The figures show X-axis, Y-axis, and Z-axis that are orthogonal to each other. The X-axis, Y-axis, and Z-axis are axes in a right-handed orthogonal coordinate system. The stacking direction of nitride semiconductor light-emitting element 100 is parallel to the Z-axis direction and the main emission direction of light (laser beam) is parallel to the Y-axis direction.

As illustrated in FIG. 2A, nitride semiconductor light-emitting element 100 includes semiconductor stack 100S including nitride semiconductor layers, and emits light from end face 100F (see FIG. 1), of semiconductor stack 100S, that is perpendicular to the stacking direction (i.e., the Z-axis direction). In the present embodiment, nitride semiconductor light-emitting element 100 is a semiconductor laser element including two end faces 100F and 100R forming a resonator. End face 100F is the front end face from which the laser beam is emitted, and end face 100R is the rear end face having a higher reflectance than end face 100F. In the present embodiment, the reflectance of end face 100F is 16% and the reflectance of end face 100R is 95%. Nitride semiconductor light-emitting element 100 also includes a waveguide formed between end face 100F and end face 100R. The resonator length (i.e., the distance between end face 100F and end face 100R) of nitride semiconductor light-emitting element 100 according to the present embodiment is approximately 1200 μm. Nitride semiconductor light-emitting element 100 emits, for example, ultraviolet light having a peak wavelength in the 375 nm band.

As illustrated in FIG. 2A, nitride semiconductor light-emitting element 100 includes substrate 101, semiconductor stack 100S, current blocking layer 110, P-side electrode 111, and N-side electrode 112. Semiconductor stack 100S includes N-type cladding layer 102, N-side first guide layer 103, N-side second guide layer 104, active layer 105, P-side first guide layer 106, electron barrier layer 107, P-type cladding layer 108, and contact layer 109.

Substrate 101 is a plate-shaped member that serves as the base of nitride semiconductor light-emitting element 100. In the present embodiment, substrate 101 is an N-type GaN substrate. Substrate 101 is doped with, for example, Si at a concentration of 1×10¹⁸ cm⁻³ as an impurity.

N-type cladding layer 102 is one example of a cladding layer disposed above substrate 101. N-type cladding layer 102 is a layer with a lower refractive index and a larger band gap energy than active layer 105. In the present embodiment, N-type cladding layer 102 is an N-type Al_{0.065}Ga_{0.935}N layer with a thickness of 540 nm. N-type cladding layer 102 is doped with Si at a concentration of 5×10¹⁷ cm⁻³ as an impurity. In the present embodiment, N-type cladding layer 102 is stacked above substrate 101 made of GaN. By thus stacking N-type cladding layer 102 above substrate 101, the lattice constant of N-type cladding layer 102 equals to the lattice constant of substrate 101. When epitaxial stacking, on N-type cladding layer 102, a nitride including at least one type of element among Al, Ga, and In while performing lattice matching, since control on a strain from each of the layers and control on the band structure and refractive index of each of the layers can be performed by adjusting the composition of each of the layers, structure control on nitride semiconductor light-emitting element 100 becomes easier. Desired properties of nitride semiconductor light-emitting element 100 can be therefore easily obtained.

N-side first guide layer 103 is one example of an N-side guide layer disposed above N-type cladding layer 102. The band gap energy of N-side first guide layer 103 is smaller than the band gap energy of N-type cladding layer 102. In other words, the refractive index of N-side first guide layer 103 is higher than the refractive index of N-type cladding layer 102. N-side first guide layer 103 is made of Al_{Xn1}Ga_{1-Xn1}N where 0<Xn1≤1. In the present embodiment, N-side first guide layer 103 is an N-type Al_{0.03}Ga_{0.97}N layer with a thickness of 100 nm. N-side first guide layer 103 is doped with Si at a concentration of 5×10¹⁷ cm⁻³ as an impurity.

N-side second guide layer 104 is one example of an N-side guide layer disposed above N-side first guide layer 103. N-side second guide layer 104 has a higher refractive index and a smaller band gap energy than N-type cladding layer 102. The band gap energy of N-side second guide layer 104 is smaller than the band gap energy of N-side first guide layer 103. In other words, the refractive index of N-side second guide layer 104 is higher than the refractive index of N-side first guide layer 103. N-side second guide layer 104 is made of Al_{Xn2}Ga_{1-Xn2}N where 0≤Xn2≤1. In the present embodiment, N-side second guide layer 104 is an undoped Al_{0.02}Ga_{0.98}N layer with a thickness of 120 nm.

Thus, in the present embodiment, the impurity concentration of N-side second guide layer 104 is lower than the impurity concentration of N-side first guide layer 103. To prevent a reduction in the series resistance of nitride semiconductor light-emitting element 100 and leakage of holes from well layer 105b to the substrate 101 side, it is effective to dope N-side first guide layer 103 and N-side second guide layer 104 each with an impurity and reduce the electrical potential of the valence band of each of the guide layers. In this case, by reducing the impurity concentration of N-side second guide layer 104 to be lower than the impurity concentration of N-side first guide layer 103, an increase in waveguide loss caused by impurities can be inhibited. In other words, by reducing the impurity concentration of N-side second guide layer 104 which is a region closer to active layer 105 than N-side first guide layer 103 is, i.e., a region having a greater light intensity, light loss caused by impurities can be reduced.

In the present embodiment, N-side second guide layer 104 is not doped with an impurity, but may be doped with an impurity. Since this lowers the resistance of N-side second guide layer 104, electrons easily flow from substrate 101 to active layer 105 and it is thus possible to reduce hole current components leaking from active layer 105 to substrate 101. As a result, it is possible to increase the thermal saturation level of light output during high-temperature operation.

Active layer 105 is a light-emitting layer disposed above N-side second guide layer 104 and having a quantum well structure. In the present embodiment, active layer 105 includes well layer 105b and barrier layers 105a and 105c, as illustrated in FIG. 2B.

Barrier layer 105a is a layer that is disposed above N-side second guide layer 104 and functions as a barrier in the quantum well structure. Barrier layer 105a is made of Al_{b}Ga_{1-b}N where 0<b≤1. In the present embodiment, barrier layer 105a is an undoped Al_{0.05}Ga_{0.95}N layer with a thickness of 12 nm.

Well layer 105b is a layer that is disposed above barrier layer 105a and functions as a well in the quantum well structure. Well layer 105b is disposed between barrier layer 105a and barrier layer 105c. In the present embodiment, well layer 105b is an undoped In_{0.01}Ga_{0.99}N layer with a thickness of 7.5 nm.

Barrier layer 105c is a layer that is disposed above well layer 105b and functions as a barrier in the quantum well structure. Barrier layer 105c is made of Al_{b}Ga_{1-b}N where 0<b≤1. In the present embodiment, barrier layer 105c is an undoped Al_{0.05}Ga_{0.95}N layer with a thickness of 10 nm.

P-side first guide layer 106 is an optical guide layer disposed above active layer 105. In the present embodiment, P-side first guide layer 106 is disposed between active layer 105 and P-type cladding layer 108. The band gap energy of P-side first guide layer 106 is smaller than the band gap energy of P-type cladding layer 108. In other words, the refractive index of P-side first guide layer 106 is higher than the refractive index of P-type cladding layer 108. In the present embodiment, P-side first guide layer 106 is a P-type Al_{0.02}Ga_{0.98}N layer with a thickness of 200 nm. P-side first guide layer 106 is doped with Mg at a concentration of 1×10¹⁸ cm⁻³ as an impurity.

Electron barrier layer 107 is a nitride semiconductor layer disposed above active layer 105. In the present embodiment, electron barrier layer 107 is disposed between P-side first guide layer 106 and P-type cladding layer 108. Electron barrier layer 107 is an Al_{Xd}Ga_{1-Xd}N layer with a thickness of 1 nm to 10 nm, inclusive, and an Al composition ratio Xd of 0.2 or more. This makes it possible to enhance the confinement effect of confining electrons to the vicinity of active layer 105, while inhibiting an increase in the operating voltage of nitride semiconductor light-emitting element 100. The concentration of the impurity with which electron barrier layer 107 is doped may be 1×10¹⁹ cm⁻³ or more. This makes it possible to enhance hole conductivity in electron barrier layer 107. Since the thickness of electron barrier layer 107 is as small as 10 nm or less, an influence on the light intensity distribution can be reduced. In the present embodiment, electron barrier layer 107 is a P-type Al_{0.36}Ga_{0.64}N layer with a thickness of 5 nm. Electron barrier layer 107 is doped with Mg at a concentration of 1×10¹⁹ cm⁻³ as an impurity. Since electron barrier layer 107 can inhibit electrons from leaking from active layer 105 to P-type cladding layer 108, the light conversion efficiency of nitride semiconductor light-emitting element 100 can be enhanced.

P-type cladding layer 108 is a P-type cladding layer disposed above active layer 105. In the present embodiment, P-type cladding layer 108 is disposed between electron barrier layer 107 and contact layer 109. The band gap energy of P-type cladding layer 108 is larger than the band gap energy of each of barrier layers 105a and 105c in active layer 105, and is also larger than the band gap energy of P-side first guide layer 106. In other words, the refractive index of P-type cladding layer 108 is lower than the refractive index of each of barrier layers 105a and 105c in active layer 105, and is also lower than the refractive index of P-side first guide layer 106. In the present embodiment, P-type cladding layer 108 is a P-type Al_{0.065}Ga_{0.935}N layer with a thickness of 450 nm. P-type cladding layer 108 is doped with Mg as an impurity. P-type cladding layer 108 includes a low-concentration region located lower than the vertical center of P-type cladding layer 108 (i.e., on the side closer to active layer 105) and having an impurity concentration lower than the impurity concentration of the remainder of P-type cladding layer 108. Specifically, P-type cladding layer 108 includes: a P-type Al_{0.065}Ga_{0.935}N layer with a thickness of 150 nm that is disposed at the lower position and doped with Mg at a concentration of 2×10¹⁸ cm⁻³; and a P-type Al_{0.065}Ga_{0.935}N layer with a thickness of 300 nm that is disposed at the upper position (i.e., on the side farther from active layer 105) and doped with Mg at a concentration of 1×10¹⁹ cm⁻³. This makes it possible to reduce free carrier loss due to impurities in P-type cladding layer 108, making it possible to reduce waveguide loss.

Ridge 108R is formed in P-type cladding layer 108 in nitride semiconductor light-emitting element 100. In addition, two trenches 108T disposed along ridge 108R and extending along the Y-axis direction are also formed in P-type cladding layer 108. In the present embodiment, ridge width W is approximately 30 μm. As illustrated in FIG. 2A, the distance between the bottom edge of ridge 108R (i.e., the bottom of trench 108T) and active layer 105 is defined as dp. The thickness of P-type cladding layer 108 at the portion below ridge 108R (i.e., the distance between the bottom edge of ridge 108R and the interface of P-type cladding layer 108 and electron barrier layer 107) is defined as dc.

Contact layer 109 is a layer that is disposed above P-type cladding layer 108 and is in ohmic contact with P-side electrode 111. In the present embodiment, contact layer 109 is a P-type GaN layer with a thickness of 100 nm. Contact layer 109 is doped with Mg at a concentration of 1×10²⁰ cm⁻³ as an impurity.

Of semiconductor stack 100S according to the present embodiment, N-type cladding layer 102, N-side first guide layer 103, N-side second guide layer 104, barrier layers 105a and 105c, P-side first guide layer 106, electron barrier layer 107, and P-type cladding layer 108 each comprise a nitride semiconductor including Al, as described above.

Current blocking layer 110 is an insulating layer that is disposed above P-type cladding layer 108 and is light-transmissive with respect to light from active layer 105. Current blocking layer 110 is disposed on the top surface of P-type cladding layer 108, except for the top surface of ridge 108R. In the present embodiment, current blocking layer 110 is a SiO₂ layer.

P-side electrode 111 is a conductive layer disposed above P-type cladding layer 108. In the present embodiment, P-side electrode 111 is disposed above contact layer 109 and current blocking layer 110. P-side electrode 111 is, for example, a single-layer film or multilayer film formed of at least one of Ag, Cr, Ti, Ni, Pd, Pt, or Au.

P-side electrode 111 may include Ag. Ag has a significantly lower refractive index with respect to light in the UV to IR range than P-type cladding layer 108 and contact layer 109. The inclusion of Ag in P-side electrode 111 inhibits light that propagates in the waveguide between two end faces 100F and 100R from seeping into P-side electrode 111, making it possible to reduce waveguide loss generated at P-side electrode 111. Ag has a refractive index of 0.5 or less in the 325 nm to 1500 nm wavelength range, inclusive, and a refractive index of 0.2 or less in the 360 nm to 950 nm wavelength range, inclusive. Moreover, Ag has a lower rate of absorption with respect to light in the UV to IR range than other metal films such as Au. Therefore, the inclusion of Ag in P-side electrode 111 can reduce light loss at P-side electrode 111.

When P-side electrode 111 includes Ag, even when the thickness of P-type cladding layer 108 is 450 nm or less, light can be inhibited from seeping into P-side electrode 111, making it possible to inhibit an increase in waveguide loss while reducing the series resistance of nitride semiconductor light-emitting element 100. This in turn makes it possible to reduce operating voltage and operating current.

When P-side electrode 111 includes Ag, the thickness of P-type cladding layer 108 may be 400 nm or less. This can further reduce the operating voltage and operating current. Furthermore, even with such a thin P-type cladding layer 108, light can be confined below P-side electrode 111 and light absorption at P-side electrode 111 can be reduced, making it possible to inhibit waveguide loss.

The thickness of P-type cladding layer 108 may be greater than the total thickness of P-side first guide layer 106, N-side first guide layer 103, and N-side second guide layer 104. This allows P-type cladding layer 108 to have a thickness sufficient enough to confine light below P-side electrode 111, making it possible to inhibit waveguide loss. When P-side electrode 111 includes Ag, the thickness of P-type cladding layer 108 may be, for example, 200 nm to 400 nm, inclusive. This makes it possible to reduce the operating voltage and operating current while inhibiting waveguide loss.

Layers with a large Al composition ratio, such as P-type cladding layer 108, has a large strain on substrate 101 made of N-type GaN. Since the total Al content in P-type cladding layer 108 can be reduced by reducing the thickness of P-type cladding layer 108, it is possible to reduce the strain on substrate 101 from P-type cladding layer 108. Accordingly, it is possible to inhibit nitride semiconductor light-emitting element 100 from cracking due to the strain from P-type cladding layer 108.

The Ag included in P-side electrode 111 may be, for example, in ohmic contact with contact layer 109. Stated differently, P-side electrode 111 may include an Ag film in ohmic contact with contact layer 109. This allows light to be confined below contact layer 109, and this in turn makes it possible to further reduce light loss at P-side electrode 111.

N-side electrode 112 is a conductive layer disposed below substrate 101 (i.e., on the principal surface of substrate 101 opposite to the principal surface of substrate 101 on which semiconductor stack 100S is disposed). N-side electrode 112 is, for example, a single-layer film or multilayer film formed of at least one of Cr, Ti, Ni, Pd, Pt, or Au

Owing to nitride semiconductor light-emitting element 100 having the above configuration, there is an effective refractive index difference ΔN between the portion below ridge 108R and the portions below trenches 108T, as illustrated in FIG. 2A. This allows the light generated in active layer 105 at the portion below ridge 108R to be confined in the horizontal direction (i.e., the X-axis direction).

### [1-2. Light Intensity Distribution]

Next, the light intensity distribution of nitride semiconductor light-emitting element 100 according to the present embodiment will be described.

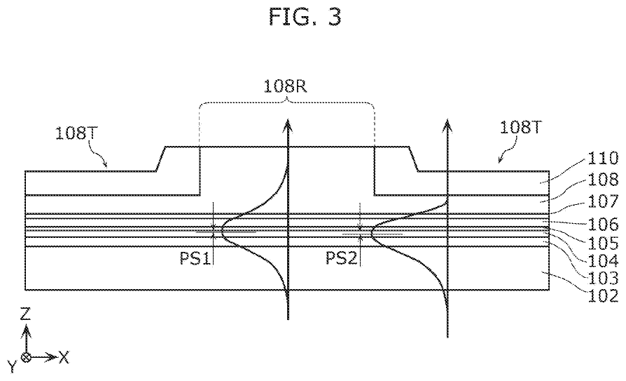

The light intensity distribution in the stacking direction (the Z-axis direction in the figures) of nitride semiconductor light-emitting element 100 according to the present embodiment will be described with reference to FIG. 3. FIG. 3 is a schematic diagram outlining the light intensity distribution in the stacking direction of nitride semiconductor light-emitting element 100 according to the present embodiment. FIG. 3 includes a schematic cross-sectional view of nitride semiconductor light-emitting element 100 and a graph outlining the light intensity distribution in the stacking direction at positions corresponding to ridge 108R and trenches 108T.

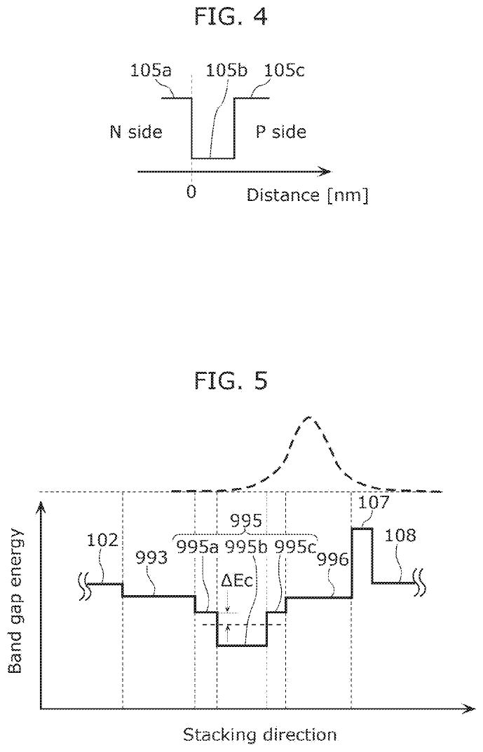

In a nitride semiconductor light-emitting element, light is generally generated in the active layer, but since the light intensity distribution in the stacking direction depends on the stacked structure, the peak of the light intensity distribution is not necessarily located in the active layer. Since the stacked structure of nitride semiconductor light-emitting element 100 according to the present embodiment differs between the portion below ridge 108R and the portions below trenches 108T, the light intensity distribution also differs between the portion below ridge 108R and the portions below trenches 108T. As illustrated in FIG. 3, the peak position of the light intensity distribution in the stacking direction at the horizontal (i.e., the X-axis direction) center of the portion below ridge 108R is PS1. The peak position of the light intensity distribution in the stacking direction in the portions below trenches 108T is PS2. Next, positions PS1 and PS2 will be described with reference to FIG. 4. FIG. 4 is a graph showing coordinates of positions in the stacking direction of nitride semiconductor light-emitting element 100 according to the present embodiment. As illustrated in FIG. 4, the coordinates of the position in the stacking direction of the N-side end face of well layer 105b in active layer 105, i.e., the end face of well layer 105b that is closer to N-type cladding layer 102 are set to zero, with the downward direction (toward N-type cladding layer 102) being the negative direction of coordinates, and the upward direction (toward P-type cladding layer 108) being the positive direction of coordinates. The absolute value of the difference between position PS1 and position PS2 is denoted as peak position difference ΔP.

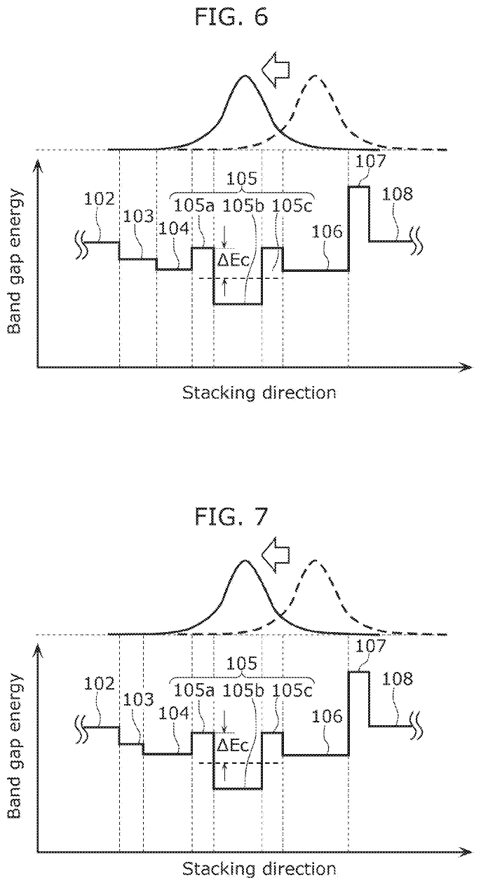

The light intensity distribution in the stacking direction at the position corresponding to ridge 108R according to the present embodiment will be described in comparison with a comparative example with reference to FIG. 5 through FIG. 7. FIG. 5 is a graph schematically showing the band gap energy distribution and the light intensity distribution in the stacking direction of a semiconductor stack according to Comparative Example 1. FIG. 6 is a graph showing the band gap energy distribution and the light intensity distribution in the stacking direction of a semiconductor stack according to the present embodiment. FIG. 7 is a graph schematically showing the band gap energy distribution and the light intensity distribution of a semiconductor stack according to a variation of the present embodiment.

The semiconductor stack according to Comparative Example 1 illustrated in FIG. 5 includes N-type cladding layer 102, N-side guide layer 993, active layer 995, P-side guide layer 996, electron barrier layer 107, and P-type cladding layer 108. The semiconductor stack according to Comparative Example 1 differs from semiconductor stack 100S according to the present embodiment in regard to the configurations of N-side guide layer 993, active layer 995, and P-side guide layer 996. In the semiconductor stack according to Comparative Example 1, N-side guide layer 993 has the same band gap energy (i.e., refractive index) and the same thickness as P-side guide layer 996. Active layer 995 includes barrier layers 995a, 995c and well layer 995b. Each of the guide layers according to Comparative Example 1 has a larger band gap energy than barrier layers 995a and 995c. In other words, each of the guide layers according to Comparative Example 1 has a lower refractive index than barrier layers 995a and 995c.

To emit ultraviolet light, it is necessary to use a cladding layer made of AlGaN having a high Al composition ratio for each of the cladding layers in each of the semiconductor stacks according to Comparative Example 1 and the present embodiment. This results in an increase in a tensile strain on substrate 101 made of GaN from each of the cladding layers made of AlGaN, and the base material of substrate 101 easily cracks in the manufacture of the nitride semiconductor light-emitting element. To inhibit such cracks in the base material, the tensile strain is inhibited by reducing the thickness of each of the cladding layers. Since electrical resistance increases in P-type cladding layer 108 made of P-type AlGaN having a high Al composition ratio, the thickness of P-type cladding layer 108 is set much thinner than the thickness of N-type cladding layer 102 and the impurity concentration of P-type cladding layer 108 is set higher than the impurity concentration of N-type cladding layer 102. Such P-type cladding layer 108 has a higher refractive index than N-type cladding layer 102.

Using a layer having a high refractive index for an active layer and each of the guide layers is demanded to guide light, but when generating ultraviolet light in the active layer, since ultraviolet light is absorbed in an InGaN layer having a high refractive index, it is not possible to use an InGaN layer for each of the guide layers and each of the barrier layers. For this reason, an AlGaN layer is used for each of the guide layers and each of the barrier layers, and an InGaN layer is used only for the well layer. Therefore, the peak position of the light intensity distribution of the semiconductor stack according to Comparative Example 1 is located more towards P-type cladding layer 108 having a high refractive index, in the direction from active layer 995 to P-type cladding layer 108, as shown in the dashed graph in FIG. 5.

In contrast, in semiconductor stack 100S according to the present embodiment, the band gap energy of each of barrier layers 105a and 105c is larger than the band gap energy of N-side second guide layer 104. In other words, when barrier layers 105a and 105c are each made of Al_{b}Ga_{1-b}N where 0<b≤1 and N-side second guide layer 104 is made of Al_{Xn2}Ga_{1-Xn2}N where 0≤Xn2≤1, b>Xn2 holds true. The band gap energy of N-side second guide layer 104 is smaller than the band gap energy of N-side first guide layer 103, and the band gap energy of N-side first guide layer 103 is smaller than the band gap energy of N-type cladding layer 102. In other words, when N-side first guide layer 103 is made of Al_{Xn1}Ga_{1-Xn1}N where 0≤Xn1≤1 and N-type cladding layer 102 is made of Al_{Xnc}Ga_{1-Xnc}N where 0≤Xnc≤1, Xn2<Xn1 and Xn1<Xnc hold true. In the present embodiment, the band gap energy of N-side second guide layer 104 that is a guide layer closer to barrier layer 105a is smaller than the band gap energy of barrier layer 105a. In other words, the refractive index of N-side second guide layer 104 is higher than the refractive index of barrier layer 105a. The refractive index of N-side second guide layer 104, which is closer to active layer 105 than N-side first guide layer 103 is, is higher than the refractive index of N-side first guide layer 103. Owing to semiconductor stack 100S having such a refractive index distribution, the light intensity distribution of semiconductor stack 100S can be shifted toward N-side second guide layer 104, compared to the semiconductor stack according to Comparative Example 1. Owing to such N-side second guide layer 104, the peak position of the light intensity distribution can be brought closer to active layer 105, compared to the semiconductor stack according to Comparative Example 1, as shown in FIG. 6. In addition, since active layer 105 is not doped with an impurity, positioning the peak position of the light intensity distribution in the vicinity of active layer 105 can reduce waveguide loss caused by light absorption due to impurities.

N-side first guide layer 103 and N-side second guide layer 104 may be collectively referred to as an N-side guide layer. In this case, the band gap energy in the lower end portion of the N-side guide layer (i.e., the band gap energy of N-side first guide layer 103) is larger than the band gap energy in the upper end portion of the N-side guide layer (i.e., the band gap energy of N-side second guide layer 104). Moreover, the band gap energy of each of barrier layers 105a and 105c is larger than the average band gap energy of the N-side guide layer. This allows the peak position of the light intensity distribution to be closer to active layer 105 compared to the semiconductor stack according to Comparative Example 1, as described above. It is also possible to inhibit cracks in the base material of substrate 101 since the thickness of each of the cladding layers can be reduced, as described above.

If the Al composition ratio of N-side first guide layer 103 is denoted by Xn1 and the Al composition ratio of N-side second guide layer 104 is denoted by Xn2, the following relationship holds true:

Xn1>Xn2

In other words, the band gap energy of N-side second guide layer 104 is smaller than the band gap energy of N-side first guide layer 103. Therefore, the peak position of the light intensity distribution can be brought closer to active layer 105 more surely compared to the semiconductor stack according to Comparative Example 1, as described above.

The semiconductor stack according to a variation of the present embodiment, which is illustrated in FIG. 7, differs from semiconductor stack 100S according to the present embodiment in that the thickness of N-side second guide layer 104 is greater than the thickness of N-side first guide layer 103. The semiconductor stack according to the variation of the present embodiment is same as semiconductor stack 100S according to the present embodiment in regard to the other aspects.

By thus increasing the thickness of N-side second guide layer 104, which has a higher refractive index than N-side first guide layer 103, to be greater than the thickness of N-side first guide layer 103, the peak position of the light intensity distribution in the stacking direction can be easily shifted toward N-type cladding layer 102. It is therefore possible to enhance the controllability of positioning the peak position of the light intensity distribution in the vicinity of active layer 105. As a result, it is possible to inhibit the peak position from being located too much towards P-side first guide layer 106 in the direction from active layer 105 to P-side first guide layer 106.

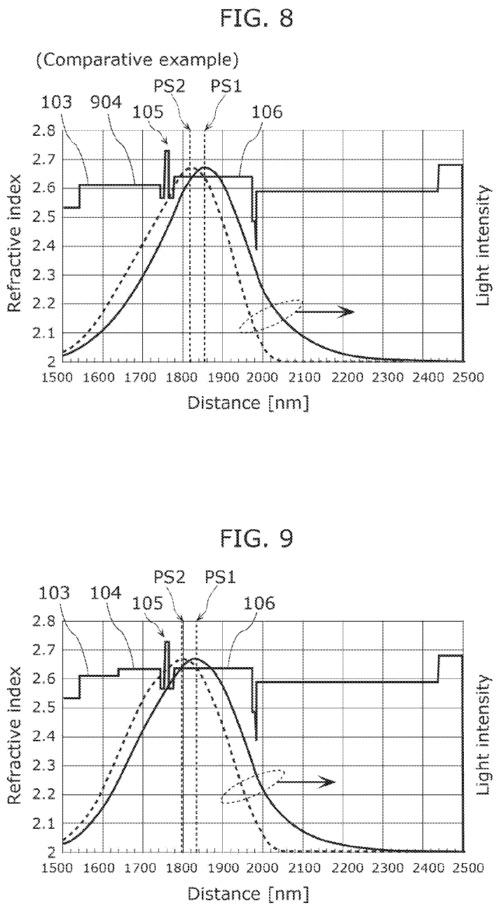

Next, peak position PS1 of the light intensity distribution in the stacking direction at the horizontal center in the portion below ridge 108R and peak position PS2 of the light intensity distribution in the stacking direction in the portions below trenches 108T in semiconductor stack 100S according to the present embodiment will be described in comparison with a semiconductor stack according to Comparative Example 2 with reference to FIG. 8 and FIG. 9. FIG. 8 is a graph showing the band gap energy distribution and the light intensity distribution of the semiconductor stack according to Comparative Example 2. FIG. 9 is a graph showing the band gap energy distribution and the light intensity distribution of semiconductor stack 100S according to the present embodiment. The semiconductor stack according to Comparative Example 2 differs from semiconductor stack 100S according to the present embodiment in that N-side second guide layer 904 has an Al composition ratio of 0.03 that is same as the Al composition ratios of N-side first guide layer 103 and P-side first guide layer 106. The semiconductor stack according to Comparative Example 2 is same as semiconductor stack 100S according to the present embodiment in regard to the other aspects.

As illustrated in FIG. 8, N-side first guide layer 103, N-side second guide layer 904, and P-side first guide layer 106 in the semiconductor stack according to Comparative Example 2 have the same Al composition ratio but different impurity concentrations. P-side first guide layer 106 therefore has a higher refractive index than N-side first guide layer 103 and N-side second guide layer 904. Accordingly, peak positions PS1 and PS2 of the respective light intensity distributions are located more towards the P-side guide layer in the direction from the active layer to the P-side guide layer. Specifically, peak position PS1 is at 96.3 nm and the peak position difference ΔP is 33.4 nm.

In contrast, in semiconductor stack 100S according to the present embodiment, since the refractive index of N-side second guide layer 104 is higher than the refractive index of N-side first guide layer 103, peak positions PS1 and PS2 of the respective light intensity distributions get closer to active layer 105, compared to the semiconductor stack according to Comparative Example 2. It is therefore possible to increase the optical confinement factor of active layer 105 and reduce waveguide loss. Both of peak positions PS1 and PS2 are brought closer to active layer 105 and the absolute value of the difference between peak position PS1 and peak position PS2 is reduced. Specifically, peak position PS1 is at 77.1 nm and the peak position difference ΔP is 32.0 nm.

In nitride semiconductor light-emitting element 100 according to the present embodiment, the effective refractive index difference ΔN between the portion below ridge 108R and the portions below trenches 108T is set to be relatively small to reduce the divergence angle of the emitted light in the horizontal direction (i.e., the X-axis direction). Specifically, the effective refractive index difference ΔN is set by adjusting distance dp between current blocking layer 110 and active layer 105 (see FIG. 2A). The effective refractive index difference ΔN decreases as distance dp increases. In the present embodiment, the effective refractive index difference ΔN is approximately 7.4×10⁻³. Therefore, in the present embodiment, there are fewer higher-order modes (i.e., higher-order transverse modes) that can propagate in the waveguide formed by ridge 108R compared to when the effective refractive index difference ΔN is larger than 7.4×10⁻³. If the effective refractive index difference ΔN decreases, the number of higher-order modes that propagate in the waveguide decreases. Therefore, of all transverse modes in the emitted light of nitride semiconductor light-emitting element 100, each higher-order mode accounts for a relatively large proportion. Accordingly, an influence made by the increase or decrease in the number of modes and the amount of change in the optical confinement factor of active layer 105 due to internode coupling is relatively large. A basic mode is defined as a 0-level mode. Therefore, when the number of modes increases or decreases and internode coupling occurs in nitride semiconductor light-emitting element 100, the linearity of light output characteristics with respect to the supplied current (so-called IL characteristics) decreases. Stated differently, a non-linear portion (also referred to as a “kink”) occurs in the graph showing IL characteristics. This may result in a decrease in the stability of the light output of nitride semiconductor light-emitting element 100.

The following describes the above-mentioned decrease in light output stability. The light distribution of light that propagates in the waveguide is two-dimensionally distributed inside ridge 108R and in regions outside ridge 108R when viewed along the normal direction of the laser end face. Since the effective refractive index decreases as the order of higher-order mode increases, the light distribution can easily spread over trenches 108T in the regions outside ridge 108R, and is easily affected by current blocking layer 110. To confine light to ridge 108R in a transverse direction, current blocking layer 110 is composed of a material with a refractive index lower than the refractive index of P-type cladding layer 108. Therefore, affected by current blocking layer 110, peak position PS2 of the stacking direction light distribution at trenches 108T in the regions outside ridge 108R is prone to be shifted toward substrate 101 in the stacking direction more than peak position PS1 of the stacking direction light distribution at ridge 108R.

Since the optical confinement effect in the horizontal direction that the waveguidable highest-order waveguide mode receives in the waveguide is weak, the waveguidable highest-order waveguide mode allows light to spread widely to trenches 108T in the regions outside ridge 108R. The stacking direction peak position at trenches 108T in the waveguidable highest-order waveguide mode is therefore the closest to substrate 101, compared to the stacking direction peak positions of other waveguide mode lights, and the average value of the peak position of the stacking direction light distribution for the horizontal direction is approximated at the stacking direction peak position at trenches 108T.

Accordingly, when light distributions are connected between modes, i.e., between the waveguidable highest-order mode and a mode whose order is lower than the order of that waveguidable highest-order mode, e.g., a basic mode, or when the order of the waveguidable highest-order transverse mode is increased due to an increase in drive current, two-dimensional deformation of the light distribution is prone to increase. Since the optical confinement factor of active layer 105 fluctuates due to such a light distribution deformation, light output stability is prone to decrease.

In nitride semiconductor light-emitting element 100 according to the present embodiment, since the effective refractive index difference ΔN is reduced in order to reduce the horizontal divergence angle of the emitted light, the number of waveguidable higher-order modes is reduced. Thus, when the number of waveguidable higher-order modes is reduced, the fluctuation of the optical confinement factor increases, and this causes a decrease in light output stability and kinks are prone to occur.

Since nitride semiconductor light-emitting element 100 according to the present embodiment includes N-side first guide layer 103, N-side second guide layer 104, and P-side first guide layer 106 each having the configuration as described above, it is possible to bring both the peak of the light intensity distribution in the portion below ridge 108R and the peak of the light intensity distribution in the portions below trenches 108T closer to active layer 105, and reduce the difference ΔP between peak position PS1 and peak position PS2 in the respective light intensity distributions. This would inhibit the positional fluctuation, in the stacking direction, of the peak position of the light intensity distribution resulting from adding the light intensity distribution in the portion below ridge 108R and the light intensity distribution in the portions below trenches 108T even if the number of modes increased or decreased and internode coupling occurred. Light output stability can be therefore enhanced.

As described above, distance dp is set to a relatively large value in order to set the effective refractive index difference ΔN to a relatively small value. In setting distance dp, if the bottom edge of ridge 108R (i.e., the bottom of trench 108T) is set below electron barrier layer 107, since the band gap energy of electron barrier layer 107 is large, holes injected from contact layer 109 are prone to leak from the lateral walls of ridge 108R to the outside of ridge 108R when passing electron barrier layer 107. As a result, the holes flow below trenches 108T. Since the light distribution intensity is low in active layer 105 below trenches 108T, the emission recoupling probability of electrons and holes injected to active layer 105 below trenches 108T decreases and the non-emission recoupling of the electrons and the holes increases. This makes nitride semiconductor light-emitting element 100 more susceptible to deterioration. For this reason, the bottom edge of ridge 108R is set above electron barrier layer 107. If distance dc from the bottom edge of ridge 108R to electron barrier layer 107 (see FIG. 2A) increases too much, holes flow from ridge 108R to the region between trenches 108T and electron barrier layer 107, and this results in leakage current. To inhibit such leakage current from increasing, distance dc is set to a value as small as possible. Distance dc may be 70 nm or less. If distance dc is 45 nm or less, a change in an oscillation threshold due to the fluctuation of distance dc can be further reduced.

### [1-3. Al Composition Ratio of Each Guide Layer]

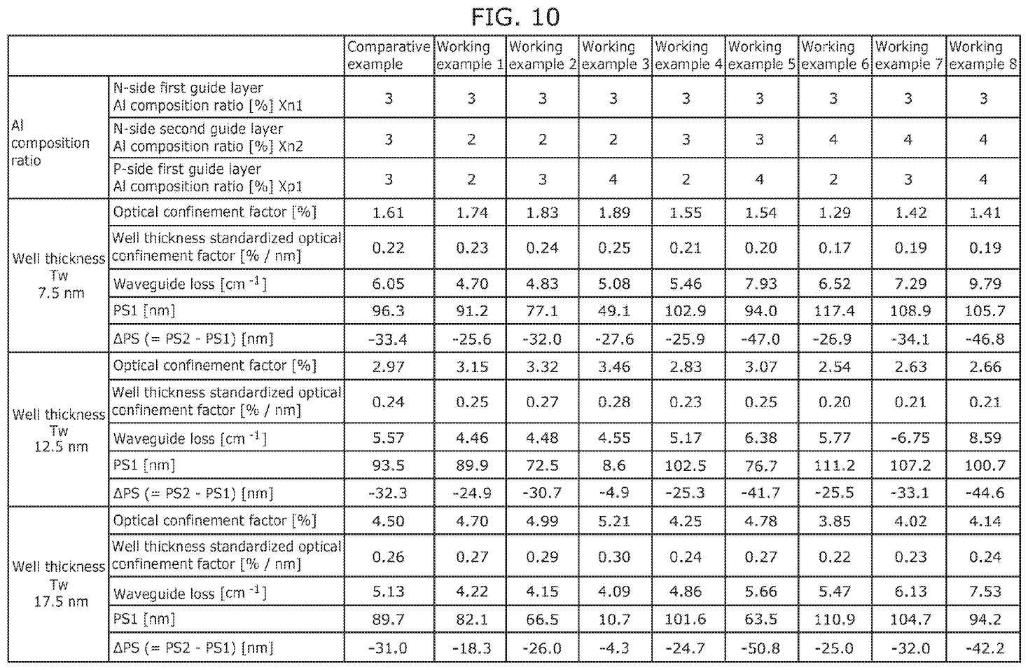

Next, the Al composition ratio of each of N-side first guide layer 103, N-side second guide layer 104, and P-side first guide layer 106 in nitride semiconductor light-emitting element 100 according to the present embodiment will be described with reference to FIG. 10. FIG. 10 is a table showing the relationship between the composition of the Al composition ratio of each of the guide layers and properties of the nitride semiconductor light-emitting element. FIG. 10 shows the relationship between (i) nine Al composition ratios including an Al composition ratio according to a comparative example and Al composition ratios according to Working Examples 1 through 8, and (ii) properties of the nitride semiconductor light-emitting element obtained through a simulation. A well thickness standardized optical confinement factor is a value obtained by dividing the optical confinement factor by thickness Tw of the well layer.

The Al composition ratio of each of the guide layers according to the comparative example is 0.03 (i.e., 3%). The Al composition ratios of the guide layers according to each of Working Examples 1 through 8 have a different combination and each of the Al composition ratios is selected from among 0.02 (i.e., 2%), 0.03 (i.e., 3%), and 0.04 (i.e., 4%). FIG. 10 also shows the properties for each of three cases where the thickness of the well layer (well thickness Tw in FIG. 10) is 7.5 nm, 12.5 nm, and 17.5 nm.

As shown in Working Examples 1 through 3, when Al composition ratio Xn2 of the N-side second guide layer is lower than Al composition ratio Xn1 of the N-side first guide layer, i.e., when the band gap energy of the N-side second guide layer is smaller than the band gap energy of the N-side first guide layer, all of the optical confinement factor, waveguide loss, peak position PS1, and the peak position difference ΔP are improved compared to the comparative example. Therefore, the band gap energy of N-side second guide layer 104 may be smaller than the band gap energy of N-side first guide layer 103, as is the case of nitride semiconductor light-emitting element 100 according to the present embodiment.

As shown in FIG. 10, the optical confinement factor, the waveguide loss, peak position PS1, and the peak position difference ΔP are improved more as thickness Tw of the well layer increases. This is attributed to the fact that the light intensity distribution in the stacking direction gets closer to the well layer by increasing the thickness of the well layer having a high refractive index. Thickness Tw of the well layer may be, for example, 10 nm or more. To achieve a quantum well active layer, thickness Tw of the well layer may be 20 nm or less.

### [1-4. Band Gap Energy of Barrier Layer]

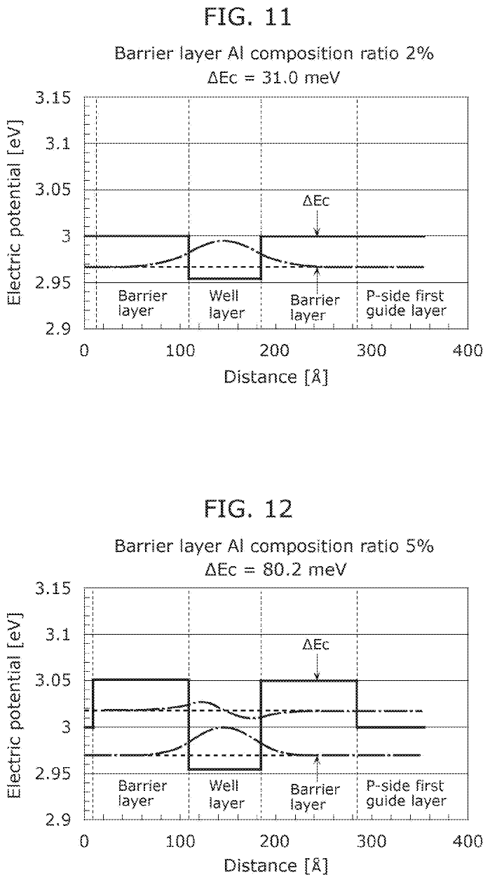

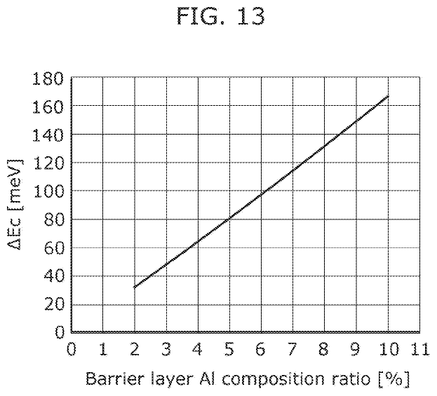

Next, the band gap energy of each of barrier layers 105a and 105c according to the present embodiment will be described with reference to FIG. 11 through FIG. 13. FIG. 11 is a graph showing the relationship between the conduction band potential energy distribution in the vicinity of active layer 105 and the electron wave function when the Al composition ratio of each of the barrier layers is 0.02. FIG. 12 is a graph showing the relationship between the conduction band potential energy distribution in the vicinity of active layer 105 and the electron wave function when the Al composition ratio of each of the barrier layers is 0.05. In each of the graphs, the horizontal axis indicates distance from a predetermined position and the vertical axis indicates electric potential. In each of the graphs, the solid line indicates the electric potential of the conduction band of each of the layers, a dashed line indicates the quantized energy level of electrons, and a dotted and dashed line indicates the electron wave function. FIG. 13 is a graph showing the relationship between the Al composition ratio of each of the barrier layers and a band offset ΔEc.

As described above, since the band gap energy of N-side second guide layer 104 adjacent to active layer 105 is small, the confinement effect of confining electrons to well layer 105b by N-side second guide layer 104 is small. For this reason, in nitride semiconductor light-emitting element 100 according to the present embodiment, the size of barrier layers 105a and 105c is increased to increase the band offset ΔEc. When the Al composition ratio of each of barrier layers 105a and 105c is 0.02 that is same as the Al composition ratio of N-side second guide layer 104, for example, the band offset ΔEc is 31 meV and leakage of electrons from barrier layer 105c cannot be sufficiently inhibited particularly during high-power operation, as illustrated in FIG. 11. In other words, the confinement effect of confining electrons to well layer 105b is small. In view of this, in the present embodiment, the Al composition ratio of each of barrier layers 105a and 105c is set to 0.05 so that the band gap energy of each of barrier layers 105a and 105c is larger than the band gap energy of N-side second guide layer 104, as illustrated in FIG. 12. This allows the band offset ΔEc to be 80.2 meV. The confinement effect of confining electrons to well layer 105b can be therefore enhanced. As illustrated in FIG. 13, the band offset ΔEc increases as the Al composition ratio of each of the barrier layers increases.

The band gap energy of each of barrier layers 105a and 105c may be larger than the band gap energy of N-side first guide layer 103. This makes it possible to further reduce leakage of electrons from well layer 105b. Since an energy difference in a base quantum level between electrons and holes formed in well layer 105b can be increased, light in a short wavelength band, such as the 375 nm wavelength band, can be easily generated in active layer 105.

When barrier layers 105a and 105c are each made of AlGaN and well layer 105b is an InGaN layer with an In composition ratio of 1% and a thickness of 7.5 nm, for example, the band offset ΔEc of 80 meV or more can be obtained by setting the Al composition ratio of each of barrier layers 105a and 105c to 0.05 or more, as illustrated in FIG. 13. This makes it possible to inhibit the leakage of electrons from well layer 105b. When well layer 105b is an InGaN layer with an In composition ratio of 1% and a thickness of 7.5 nm, for example, the band offset ΔEc of 167 meV or more can be obtained by setting the Al composition ratio of each of barrier layers 105a and 105c to 0.10 or more.

Since increasing the thickness of well layer 105b reduces the difference between the quantum level of electrons and the conduction band potential energy of well layer 105b, the band offset ΔEc can be further increased.

### [1-5. Al Composition Ratio and Thickness of Each Cladding Layer]

Next, the Al composition ratio and thickness of each of the cladding layers in nitride semiconductor light-emitting element 100 according to the present embodiment will be described.

### [1-5-1. Waveguide Loss and Optical Confinement Factor]

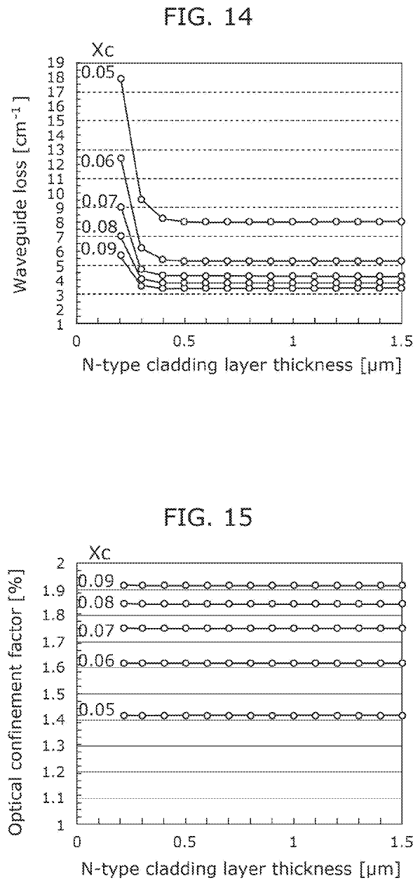

First, (i) the relationship between the Al composition ratio and thickness of each of the cladding layers in nitride semiconductor light-emitting element 100 and waveguide loss, and (ii) the relationship between the Al composition ratio and thickness of each of the cladding layers in nitride semiconductor light-emitting element 100 and the optical confinement factor will be described with reference to FIG. 14 and FIG. 15. FIG. 14 is a graph showing the relationship between the thickness of N-type cladding layer 102 in nitride semiconductor light-emitting element 100 according to the present embodiment and waveguide loss. FIG. 15 is a graph showing the relationship between the thickness of N-type cladding layer 102 in nitride semiconductor light-emitting element 100 according to the present embodiment and the optical confinement factor. The graphs in FIG. 14 and FIG. 15 were obtained through a simulation. In the present simulation, waveguide loss and the optical confinement factor are calculated under the condition that same Al composition ratio Xc is defined for both the Al composition ratio of N-type cladding layer 102 and the Al composition ratio of P-type cladding layer 108, and Al composition ratio Xc and the thickness of N-type cladding layer 102 are varied. FIG. 14 shows the waveguide loss corresponding to each of the cases where Al composition ratio Xc is 0.05, 0.06, 0.07, 0.08, and 0.09. FIG. 15 shows the optical confinement factor corresponding to each of the cases where Al composition ratio Xc is 0.05, 0.06, 0.07, 0.08, and 0.09. In nitride semiconductor light-emitting element 100 with which the calculation is performed in the present simulation, a buffer layer is provided between substrate 101 and N-type cladding layer 102. The buffer layer includes an N-type Al_{0.007}Ga_{0.993}N layer with a thickness of 1000 nm and an N-type In_{0.05}Ga_{0.95}N layer with a thickness of 150 nm that are sequentially stacked on substrate 101. The buffer layer is doped with Si at a concentration of 5×10¹⁷ cm⁻³ as an impurity.

As shown in FIG. 14, there is a tendency that waveguide loss increases when the thickness of N-type cladding layer 102 is less than 0.5 μm. This is probably attributed to the leakage of light to the outside of N-type cladding layer 102 (i.e., substrate 101 and the buffer layer), and the leaking light is absorbed or propagates in the substrate in a substrate mode. By setting the thickness of N-type cladding layer 102 to 0.5 μm or more, such waveguide loss can be reduced. Since the refractive index of each of the cladding layers decreases and the optical confinement factor increases as shown in FIG. 15 as the Al composition ratio of each of the cladding layers increases, waveguide loss decreases. Particularly by setting the Al composition ratio to 0.06 or more, waveguide loss can be significantly reduced compared to waveguide loss corresponding to when the Al composition ratio is 0.05. Even when the Al composition ratio is set higher than 0.08, the amount of reduction in waveguide loss is small compared to waveguide loss corresponding to when the Al composition ratio is 0.08. If the Al composition ratio is increased, however, a tensile strain on substrate 101 from semiconductor stack 100S increases. The Al composition ratio may be set to 0.08 to inhibit such an increase in the tensile strain.

### [1-5-2. Bow Amount]

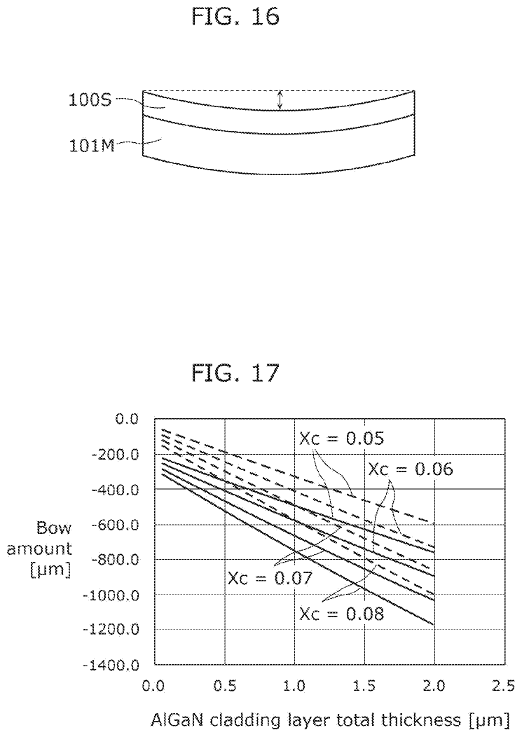

Next, the amount of bow due to a strain on nitride semiconductor light-emitting element 100 according to the present embodiment will be described with reference to FIG. 16. FIG. 16 is a schematic lateral view of bow of base material 101M of substrate 101 according to the present embodiment and semiconductor stack 100S which occurs when semiconductor stack 100S is stacked on base material 101M. Base material 101M of substrate 101 illustrated in FIG. 16 is, for example, a GaN substrate of two inches in diameter. When stacking (i.e., allowing crystal growth of) semiconductor stack 100S on base material 101M, base material 101M and semiconductor stack 100S bow due to a tensile strain on base material 101M generated by AlGaN layers in semiconductor stack 100S. In the present embodiment, the top surface of semiconductor stack 100S bows in a direction such that the top surface is recessed, due to the tensile strain on base material 101M generated by the AlGaN layers.

The bow amount of base material 101M and semiconductor stack 100S will be described with reference to FIG. 17. FIG. 17 is a graph showing the amount of bow of base material 101M of substrate 101 according to the present embodiment and semiconductor stack 100S which occurs when semiconductor stack 100S is stacked on base material 101M. In the graph in FIG. 17, the horizontal axis indicates the total thickness of N-type cladding layer 102 and P-type cladding layer 108 each made of Al_{Xc}Ga_{1-Xc}N and included in semiconductor stack 100S. The vertical axis in the graph indicates bow amount. The bow amount corresponding to when the top surface of semiconductor stack 100S is recessed (i.e., the depth of the recessed portion indicated by the arrow in FIG. 16), as illustrated in FIG. 16, is presented by a negative numerical value. The bow amount corresponding to when the top surface of semiconductor stack 100S protrudes (i.e., the height of the protruding portion) is presented by a positive numerical value.

In FIG. 17, the simulation result of the bow amount when the thickness of N-type cladding layer 102 is varied in nitride semiconductor light-emitting element 100 described above is indicated by solid lines. FIG. 17 shows the bow amount corresponding to each of the cases where the Al composition ratio Xc of each of N-type cladding layer 102 and P-type cladding layer 108 is 0.05, 0.06, 0.07, and 0.08. In the simulation, a disk-shaped GaN substrate of two inches in diameter is used as base material 101M.

In FIG. 17, the bow amount corresponding to when a buffer layer is provided between base material 101M and N-type cladding layer 102 to reduce the strain and the bow amount is also indicated by dashed lines. The buffer layer includes an N-type Al_{0.007}Ga_{0.993}N layer with a thickness of 300 nm and an N-type In_{0.05}Ga_{0.95}N layer with a thickness of 150 nm that are sequentially stacked on base material 101M. The buffer layer is doped with Si at a concentration of 5×10¹⁷ cm⁻³ as an impurity.

As illustrated in FIG. 17, the absolute value of the bow amount increases as the Al composition ratio of each of the cladding layers increases and also as the total thickness of the cladding layers increases. This is attributed to the fact that a tensile strain on base material 101M made of GaN increases as the Al composition ratio of each of the AlGaN layers increases or as the thickness of each of the AlGaN layers increases.

When using a GaN substrate of two inches in diameter as base material 101M, a risk that base material 101M cracks increases if the absolute value of the bow amount exceeds 800 μm. In view of this, to achieve 700 μm or less for the absolute value of the bow amount of base material 101M, the total thickness of the cladding layers may be 1.1 μm or less when, for example, Al composition ratio Xc is 0.06 to 0.07, inclusive. Moreover, by setting the thickness of N-type cladding layer 102 to 0.5 μm or more, i.e., setting the total thickness of P-type cladding layer 108 with a thickness of 450 nm (i.e., 0.45 μm) and N-type cladding layer 102 to 0.95 μm or more, it is possible to inhibit waveguide loss and increase the optical confinement factor, as described above with reference to FIG. 14 and FIG. 15. Accordingly, by thus setting Al composition ratio Xc to 0.06 to 0.07, inclusive, and the total thickness of the cladding layers to 0.95 μm to 1.1 μm, inclusive, it is possible to achieve a waveguide with a large optical confinement factor and small loss while inhibiting cracks in base material 101M. In addition, by setting the total thickness of the cladding layers to 1.0 μm or less, the absolute value of the bow amount of base material 101M can be further reduced, making it possible to more surely inhibit cracks in base material 101M.

As indicated by the dashed lines in FIG. 17, the absolute value of the bow amount can be reduced by providing a buffer layer between base material 101M and N-type cladding layer 102. It is therefore possible, when a buffer layer is provided, to further increase the total thickness of the cladding layers and the Al composition ratio of each of the cladding layers while inhibiting cracks in base material 101M.

### [1-6. Thickness of Each Guide Layer]

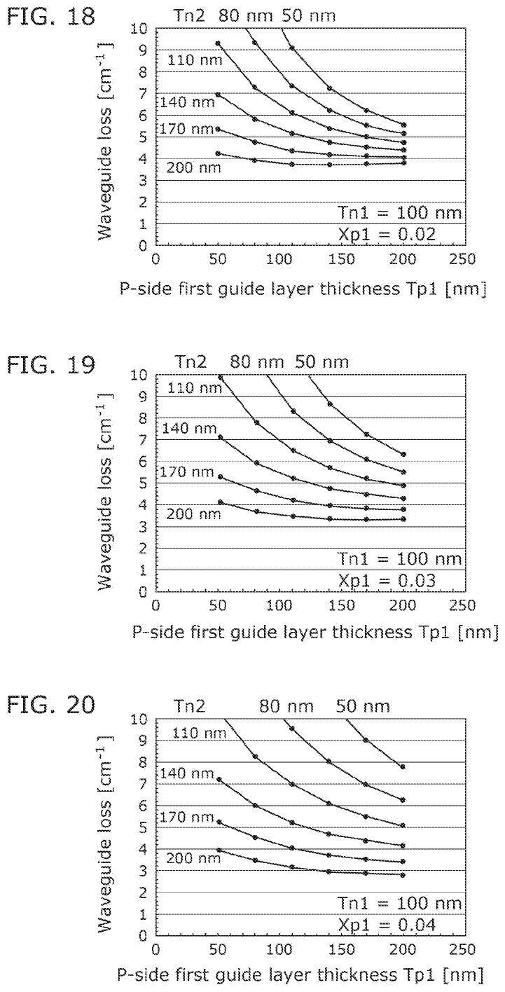

Next, the relationship between (i) the thicknesses of N-side first guide layer 103, N-side second guide layer 104, and P-side first guide layer 106, and (ii) waveguide loss will be described with reference to FIG. 18 through FIG. 20. FIG. 18 through FIG. 20 are each a graph showing the relationship between the guide layers according to the present embodiment and waveguide loss obtained through a simulation. In each of FIG. 18 through FIG. 20, the horizontal axis indicates thickness Tp1 of P-side first guide layer 106 and the vertical axis indicates waveguide loss. Each of FIG. 18 through FIG. 20 illustrates a graph showing each of the cases where thickness Tn2 of N-side second guide layer 104 is varied by 30 nm from 50 nm to 200 nm. Thickness Tn1 of N-side first guide layer 103 is 100 nm. FIG. 18, FIG. 19, and FIG. 20 show the cases where Al composition ratio Xp1 of P-side first guide layer 106 is 0.02, 0.03, and 0.04, respectively.

As shown in FIG. 18 through FIG. 20, waveguide loss can be reduced as thickness Tn2 of N-side second guide layer 104 increases. This is because the peak position of the light intensity distribution in the stacking direction can be shifted in the direction from P-type cladding layer 108 to active layer 105 owing to an increase in thickness Tn2 of N-side second guide layer 104 having a higher refractive index than N-type cladding layer 102 and N-side first guide layer 103. In addition, since active layer 105 is not doped with an impurity, the peak position of the light intensity distribution getting closer to active layer 105 can reduce waveguide loss due to impurities.

As shown in FIG. 18 through FIG. 20, when thickness Tn2 of N-side second guide layer 104 is greater than thickness Tn1 (=100 nm) of N-side first guide layer 103, waveguide loss can be further reduced.

When thickness Tp1 of P-side first guide layer 106 is small, waveguide loss tends to increase. Accordingly, thickness Tp1 of P-side first guide layer 106 may be 65 nm or more to reduce waveguide loss. When thickness Tn2 of N-side second guide layer 104 is 150 nm or more, an influence that thickness Tp1 of P-side first guide layer 106 has on waveguide loss decreases. In other words, when thickness Tn2 of N-side second guide layer 104 is 150 nm or more, waveguide loss is approximately constant although thickness Tp1 of P-side first guide layer 106 varies. Accordingly, thickness Tn2 of N-side second guide layer 104 may be 150 nm or more to increase the flexibility of thickness Tp1 of P-side first guide layer 106.

### Embodiment 2

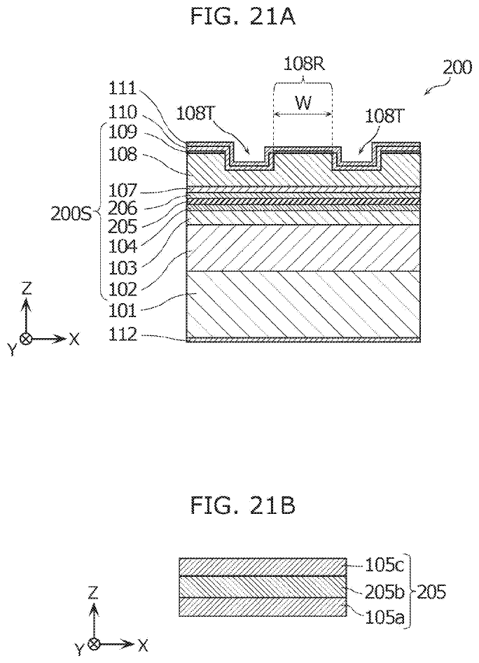

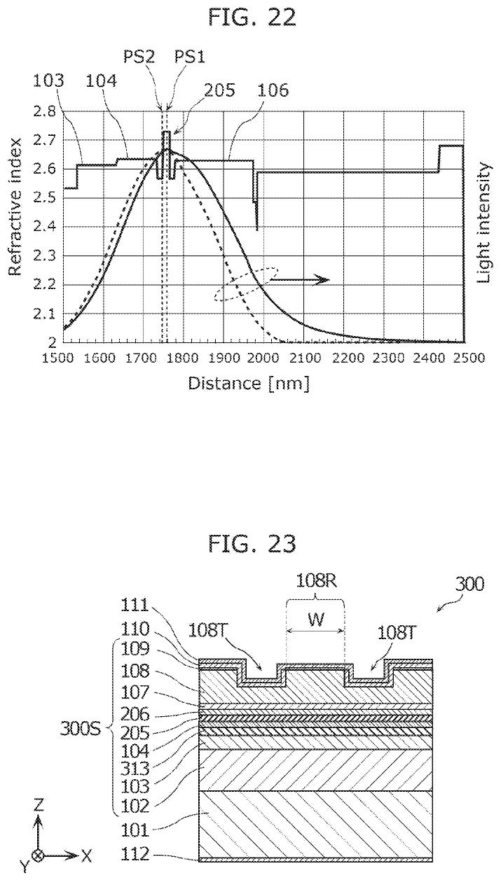

A nitride semiconductor light-emitting element according to Embodiment 2 will be described. The nitride light emitting element according to the present embodiment differs from nitride semiconductor light-emitting element 100 according to Embodiment 1 in regard mainly to the configuration of the well layer. Hereinafter, the nitride semiconductor light-emitting element according to the present embodiment will be described with reference to FIG. 21A through FIG. 22, focusing on the difference from nitride semiconductor light-emitting element 100 according to Embodiment 1.

FIG. 21A is a schematic cross-sectional view of the overall configuration of nitride semiconductor light-emitting element 200 according to the present embodiment. FIG. 21B is a schematic cross-sectional view of the configuration of active layer 205 included in nitride semiconductor light-emitting element 200 according to the present embodiment. FIG. 22 is a graph schematically showing the light intensity distribution and the band gap energy distribution in the stacking direction of semiconductor stack 200S according to the present embodiment.

As illustrated in FIG. 21A, nitride semiconductor light-emitting element 200 according to the present embodiment includes substrate 101, semiconductor stack 200S, current blocking layer 110, P-side electrode 111, and N-side electrode 112. Semiconductor stack 200S includes N-type cladding layer 102, N-side first guide layer 103, N-side second guide layer 104, active layer 205, P-side first guide layer 206, electron barrier layer 107, P-type cladding layer 108, and contact layer 109.

Active layer 205 according to the present embodiment includes well layer 205b and barrier layers 105a and 105c, as illustrated in FIG. 21B. Well layer 205b according to the present embodiment is an undoped In_{0.01}Ga_{0.99}N layer with a thickness of 17.5 nm. Thus, in the present embodiment, the thickness of well layer 205b is 10 nm or more. By thus increasing the thickness of well layer 205b having a high refractive index, the light intensity distribution in the stacking direction can be brought closer to well layer 205b. Therefore, the optical confinement factor, waveguide loss, and peak position difference ΔP of nitride semiconductor light-emitting element 200 can be further improved.

In the present embodiment, P-side first guide layer 206 is a P-type Al_{0.04}Ga_{0.96}N layer with a thickness of 200 nm. P-side first guide layer 206 is doped with Mg at a concentration of 1×10¹⁸ cm⁻³ as an impurity. Thus, in the present embodiment, the band gap energy of P-type cladding layer 108 made of Al_{0.065}Ga_{0.935}N is larger than the band gap energy of P-side first guide layer 206. The band gap energy of P-side first guide layer 206 is larger than the average band gap energy of an N-side guide layer including N-side first guide layer 103 made of Al_{0.03}Ga_{0.97}N and N-side second guide layer 104 made of Al_{0.02}Ga_{0.98}N. In other words, the refractive index of P-side first guide layer 206 is lower than the average refractive index of the N-side guide layer. This makes it possible to shift the peak position of the light intensity distribution in the direction from P-side first guide layer 206 to the N-side guide layer (i.e., downward). Therefore, in the present embodiment, the peak position of the light intensity distribution can be brought closer to active layer 205, compared to Comparative Example 1 described in Embodiment 1.

In the present embodiment, the following relationship holds true when N-type cladding layer 102 is made of Al_{Xnc}Ga_{1-Xnc}N, the N-side guide layer is made of AlGaN, barrier layers 105a and 105c are each made of Al_{b}Ga_{1-b}N, P-side first guide layer 206 is made of AlGaN, electron barrier layer 107 is made of Al_{Xd}Ga_{1-Xd}N, and P-type cladding layer 108 is made of Al_{Xpc}Ga_{1-Xpc}N:

b>Xn, Xp1≥Xg3, Xnc>Xn, and Xpc>Xp1,

where Xn denotes the average Al composition ratio of the N-side guide layer and Xp1 denotes the average Al composition ratio of P-side first guide layer 206. Since b>Xn holds true, the band gap energy of each of barrier layers 105a and 105c is larger than the average band gap energy of the N-side guide layer. In other words, the refractive index of each of barrier layers 105a and 105c is lower than the refractive index of the N-side guide layer. This makes it possible to shift the peak position of the light intensity distribution in the direction from barrier layers 105a and 105c to the N-side guide layer (i.e., downward). Therefore, the peak position of the light intensity distribution can be brought closer to active layer 205, compared to Comparative Example 1 described in Embodiment 1.

According to the present embodiment, it is possible to achieve nitride semiconductor light-emitting element 200 where the effective refractive index difference ΔN is 4.3×10⁻³, peak position PS1 of the light intensity distribution in the stacking direction at the portion below ridge 108R is 8.9 nm, the peak position difference ΔP is 4.2 nm, the optical confinement factor of active layer 205 is 5.2%, and waveguide loss is 3.7 cm⁻¹.

### Embodiment 3

A nitride semiconductor light-emitting element according to Embodiment 3 will be described. The nitride semiconductor light-emitting element according to the present embodiment differs from nitride semiconductor light-emitting element 200 according to Embodiment 2 in regard to the inclusion of a hole barrier layer. Hereinafter, the nitride semiconductor light-emitting element according to the present embodiment will be described with reference to FIG. 23, focusing on the difference from nitride semiconductor light-emitting element 200 according to Embodiment 2.

FIG. 23 is a schematic cross-sectional view of the overall configuration of nitride semiconductor light-emitting element 300 according to the present embodiment. As illustrated in FIG. 23, nitride semiconductor light-emitting element 300 according to the present embodiment includes substrate 101, semiconductor stack 300S, current blocking layer 110, P-side electrode 111, and N-side electrode 112. Semiconductor stack 300S includes N-type cladding layer 102, N-side first guide layer 103, hole barrier layer 313, N-side second guide layer 104, active layer 205, P-side first guide layer 206, electron barrier layer 107, P-type cladding layer 108, and contact layer 109.

Hole barrier layer 313 is a nitride semiconductor layer that is disposed between N-type cladding layer 102 and active layer 205 and inhibits holes from leaking from active layer 205 to N-type cladding layer 102. In the present embodiment, hole barrier layer 313 is disposed between N-side first guide layer 103 and N-side second guide layer 104. Hole barrier layer 313 is an N-type Al_{0.30}Ga_{0.70}N layer with a thickness of 4 nm. Hole barrier layer 313 is doped with Si at a concentration of 5×10¹⁷ cm⁻³ as an impurity. Nitride semiconductor light-emitting element 300 thus includes hole barrier layer 313 having a higher Al composition ratio than N-type cladding layer 102 and barrier layers 105a and 105c. This makes it possible to enhance the confinement effect of confining holes to the vicinity of active layer 205, while inhibiting an increase in operating voltage. Hole barrier layer 313 may be doped with an impurity with a concentration of 5×10¹⁷ cm⁻³ or more. This makes it possible to enhance electron conduction in hole barrier layer 313. The thickness of hole barrier layer 313 is, for example, 1 nm to 10 nm, inclusive. By thus reducing the thickness of hole barrier layer 313, an influence that hole barrier layer 313 has on the light intensity distribution can be reduced. Therefore, nitride semiconductor light-emitting element 300 according to the present embodiment produces the same advantageous effects as nitride semiconductor light-emitting element 200 according to Embodiment 2.

According to the present embodiment, it is possible to achieve nitride semiconductor light-emitting element 300 where the effective refractive index difference ΔN is 4.9×10⁻³, peak position PS1 of the light intensity distribution in the stacking direction at the portion below ridge 108R is 10.8 nm, the peak position difference ΔP is 4.3 nm, the optical confinement factor of active layer 205 is 5.2%, and waveguide loss is 5.2 cm⁻¹.

### Embodiment 4

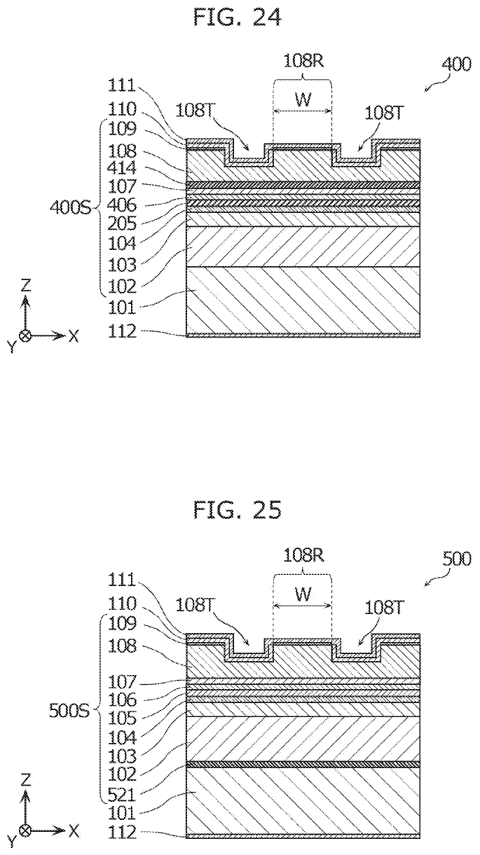

A nitride semiconductor light-emitting element according to Embodiment 4 will be described. The nitride semiconductor light-emitting element according to the present embodiment differs from nitride semiconductor light-emitting element 200 according to Embodiment 2 in regard to the inclusion of a P-side second guide layer. Hereinafter, the nitride semiconductor light-emitting element according to the present embodiment will be described with reference to FIG. 24, focusing on the difference from nitride semiconductor light-emitting element 200 according to Embodiment 2.

FIG. 24 is a schematic cross-sectional view of the overall configuration of nitride semiconductor light-emitting element 400 according to the present embodiment. As illustrated in FIG. 24, nitride semiconductor light-emitting element 400 according to the present embodiment includes substrate 101, semiconductor stack 400S, current blocking layer 110, P-side electrode 111, and N-side electrode 112. Semiconductor stack 400S includes N-type cladding layer 102, N-side first guide layer 103, N-side second guide layer 104, active layer 205, P-side first guide layer 406, electron barrier layer 107, P-side second guide layer 414, P-type cladding layer 108, and contact layer 109.

P-side second guide layer 414 is an optical guide layer disposed between P-side first guide layer 406 and P-type cladding layer 108. In the present embodiment, P-side second guide layer 414 is disposed between electron barrier layer 107 and P-type cladding layer 108. P-side second guide layer 414 is a P-type Al_{0.04}Ga_{0.96}N layer with a thickness of 50 nm. P-side second guide layer 414 is doped with Mg at a concentration of 2×10¹⁸ cm⁻³ as an impurity.

In the present embodiment, P-side first guide layer 406 is a P-type Al_{0.04}Ga_{0.96}N layer with a thickness of 150 nm. P-side first guide layer 406 is doped with Mg at a concentration of 1×10¹⁸ cm⁻³ as an impurity. In other words, in the present embodiment, the thickness of P-side first guide layer 406 is less, by 50 nm, than the thickness of P-side first guide layer 206 according to Embodiment 2. When nitride semiconductor light-emitting element 400 thus has P-side second guide layer 414, the thickness of P-side first guide layer 406 may be reduced by the thickness of P-side second guide layer 414.

In the present embodiment, nitride semiconductor light-emitting element 400 thus includes P-side second guide layer 414 disposed between electron barrier layer 107 and P-type cladding layer 108, and the thickness of P-side first guide layer 406 is less than the thickness of P-side first guide layer 206 according to Embodiment 2 by the thickness of P-side second guide layer 414. Stated differently, in the present embodiment, electron barrier layer 107 is disposed closer to well layer 205b in active layer 205 by the thickness of P-side second guide layer 414, compared to electron barrier layer 107 according to Embodiment 2. By thus placing electron barrier layer 107 closer to well layer 205b, current leaking from active layer 205 to P-type cladding layer 108 can be further inhibited by electron barrier layer 107.

According to the present embodiment, it is possible to achieve nitride semiconductor light-emitting element 400 where the effective refractive index difference ΔN is 7.4×10⁻³, peak position PS1 of the light intensity distribution in the stacking direction at the portion below ridge 108R is 9.1 nm, the peak position difference ΔP is 6.9 nm, the optical confinement factor of active layer 205 is 5.4%, and waveguide loss is 4.5 cm⁻¹.

### Embodiment 5

A nitride semiconductor light-emitting element according to Embodiment 5 will be described. The nitride semiconductor light-emitting element according to the present embodiment differs from nitride semiconductor light-emitting element 100 according to Embodiment 1 in regard to the inclusion of a buffer layer. Hereinafter, the nitride semiconductor light-emitting element according to the present embodiment will be described with reference to FIG. 25, focusing on the difference from nitride semiconductor light-emitting element 100 according to Embodiment 1.

FIG. 25 is a schematic cross-sectional view of the overall configuration of nitride semiconductor light-emitting element 500 according to the present embodiment. As illustrated in FIG. 25, nitride semiconductor light-emitting element 500 according to the present embodiment includes substrate 101, semiconductor stack 500S, current blocking layer 110, P-side electrode 111, and N-side electrode 112. Semiconductor stack 500S includes first buffer layer 521, N-type cladding layer 102, N-side first guide layer 103, N-side second guide layer 104, active layer 105, P-side first guide layer 106, electron barrier layer 107, P-type cladding layer 108, and contact layer 109.

First buffer layer 521 is disposed between substrate 101 and N-type cladding layer 102 and includes In. In the present embodiment, first buffer layer 521 is an N-type In_{0.05}Ga_{0.95}N layer with a thickness of 150 nm. First buffer layer 521 is doped with Si at a concentration of 5×10¹⁷ cm⁻³ as an impurity. If first buffer layer 521 that is made of InGaN and imposes a compressive strain on substrate 101 is disposed between substrate 101 made of GaN and N-type cladding layer 102, the amount of tensile strain from the entire semiconductor stack 500S decreases. It is therefore possible to reduce the recessed bow of base material 101M of substrate 101, which is described in Embodiment 1. In other words, the flatness of base material 101M can be improved. Therefore, cracks in base material 101M can be inhibited.

According to the present embodiment, it is possible to achieve nitride semiconductor light-emitting element 500 where the effective refractive index difference ΔN is 7.4×10⁻³, peak position PS1 of the light intensity distribution in the stacking direction at the portion below ridge 108R is 96.0 nm, the peak position difference ΔP is −26.3 nm, the optical confinement factor of active layer 105 is 1.69%, and waveguide loss is 4.65 cm⁻¹.

### Variation 1 of Embodiment 5

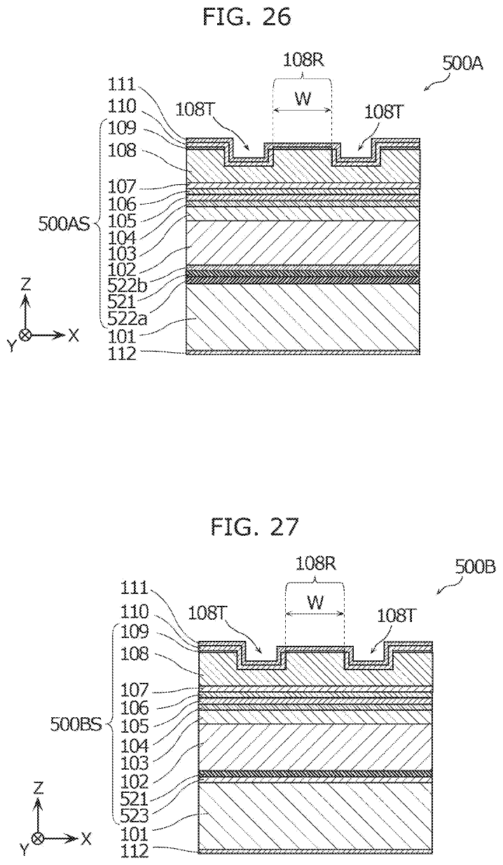

A nitride semiconductor light-emitting element according to Variation 1 of Embodiment 5 will be described. The nitride semiconductor light-emitting element according to the present variation differs from nitride semiconductor light-emitting element 500 according to Embodiment 5 in regard to the inclusion of second buffer layers. Hereinafter, the nitride semiconductor light-emitting element according to the present variation will be described with reference to FIG. 26, focusing on the difference from nitride semiconductor light-emitting element 500 according to Embodiment 5.

FIG. 26 is a schematic cross-sectional view of the overall configuration of nitride semiconductor light-emitting element 500A according to the present variation. As illustrated in FIG. 26, nitride semiconductor light-emitting element 500A according to the present variation includes substrate 101, semiconductor stack 500AS, current blocking layer 110, P-side electrode 111, and N-side electrode 112. Semiconductor stack 500AS includes first buffer layer 521, second buffer layers 522a and 522b, N-type cladding layer 102, N-side first guide layer 103, N-side second guide layer 104, active layer 105, P-side first guide layer 106, electron barrier layer 107, P-type cladding layer 108, and contact layer 109.

Second buffer layers 522a and 522b are buffer layers each of which is disposed on a different one of principal surfaces of first buffer layer 521 and is made of GaN. In the present variation, second buffer layer 522a is disposed on the principal surface of first buffer layer 521 facing substrate 101 (i.e., the lower principal surface), and second buffer layer 522b is disposed on the principal surface of first buffer layer 521 facing N-type cladding layer 102 (i.e., the upper principal surface). In other words, second buffer layer 522a, first buffer layer 521, second buffer layer 522b, and N-type cladding layer 102 are sequentially stacked on substrate 101. In the present variation, second buffer layers 522a and 522b are each an N-type GaN layer with a thickness of 10 nm. Second buffer layer 522a is doped with Si at a concentration of 5×10¹⁷ cm⁻³ as an impurity and second buffer layer 522b is doped with Si at a concentration of 1×10¹⁸ cm⁻³ as an impurity.

By thus stacking, on second buffer layer 522a made of GaN, first buffer layer 521 that is made of InGaN and imposes a compressive strain, after second buffer layer 522a is stacked above substrate 101, the generation of lattice defects at the lower principal surface of first buffer layer 521 (i.e., the interface with second buffer layer 522a) can be inhibited. In addition, by stacking second buffer layer 522b between first buffer layer 521 and N-type cladding layer 102, it is possible to reduce the difference between compressive stress and tensile stress generated between first buffer layer 521 and N-type cladding layer 102. This makes it possible to reduce shear stress between first buffer layer 521 and N-type cladding layer 102. Therefore, cracks in nitride semiconductor light-emitting element 500A can be reduced in processing processes after the crystal growth of semiconductor stack 500AS on base material 101M of substrate 101.

In the present variation, it is possible to achieve nitride semiconductor light-emitting element 500A where the effective refractive index difference ΔN is 7.4×10⁻³, peak position PS1 of the light intensity distribution in the stacking direction at the portion below ridge 108R is 96.0 nm, the peak position difference ΔP is −26.3 nm, the optical confinement factor of active layer 105 is 1.69%, and waveguide loss is 4.65 cm⁻¹, as is the case of nitride semiconductor light-emitting element 500 according to Embodiment 5.

### Variation 2 of Embodiment 5

A nitride semiconductor light-emitting element according to Variation 2 of Embodiment 5 will be described. The nitride semiconductor light-emitting element according to the present variation differs from nitride semiconductor light-emitting element 500 according to Embodiment 5 in regard to the additional inclusion of a third buffer layer. Hereinafter, the nitride semiconductor light-emitting element according to the present variation will be described with reference to FIG. 27, focusing on the difference from nitride semiconductor light-emitting element 500 according to Embodiment 5.

FIG. 27 is a schematic cross-sectional view of the overall configuration of nitride semiconductor light-emitting element 500B according to the present variation. As illustrated in FIG. 27, nitride semiconductor light-emitting element 500B according to the present variation includes substrate 101, semiconductor stack 500BS, current blocking layer 110, P-side electrode 111, and N-side electrode 112. Semiconductor stack 500BS includes third buffer layer 523, first buffer layer 521, N-type cladding layer 102, N-side first guide layer 103, N-side second guide layer 104, active layer 105, P-side first guide layer 106, electron barrier layer 107, P-type cladding layer 108, and contact layer 109.

Third buffer layer 523 is one example of an intermediate buffer layer that is disposed between substrate 101 and first buffer layer 521 and includes Al. In the present variation, third buffer layer 523 is an N-type Al_{0.007}Ga_{0.993}N layer with a thickness of 1000 nm (i.e., 1 μm). Third buffer layer 523 is doped with Si at a concentration of 5×10¹⁷ cm⁻³ as an impurity.

If third buffer layer 523 made of AlGaN is thus stacked between substrate 101 made of GaN and first buffer layer 521 made of InGaN, the flatness of the surface of first buffer layer 521 during crystal growth can be improved. The flatness of the growth surface of each semiconductor layer that crystal grows on first buffer layer 521 can be therefore improved. If the Al composition ratio of third buffer layer 523 increases, a tensile strain from third buffer layer 523 increases and the amount of recessed bow of base material 101M of substrate 101 increases. To reduce such a bow amount, the Al composition ratio of third buffer layer 523 is set to 0.01 or less.

If first buffer layer 521 that imposes a compressive strain on substrate 101 is stacked on third buffer layer 523, the bow of base material 101M of substrate 101 can be reduced. In other words, the flatness of base material 101M can be improved. It is therefore possible to inhibit cracks that occur in processing processes after the crystal growth on base material 101M.

In the present variation, it is possible to achieve nitride semiconductor light-emitting element 500B where the effective refractive index difference ΔN is 7.4×10⁻³, peak position PS1 of the light intensity distribution in the stacking direction at the portion below ridge 108R is 96.0 nm, the peak position difference ΔP is −26.3 nm, the optical confinement factor of active layer 205 is 1.69%, and waveguide loss is 4.65 cm⁻¹, as is the case of nitride semiconductor light-emitting element 500 according to Embodiment 5.

### Variation 3 of Embodiment 5

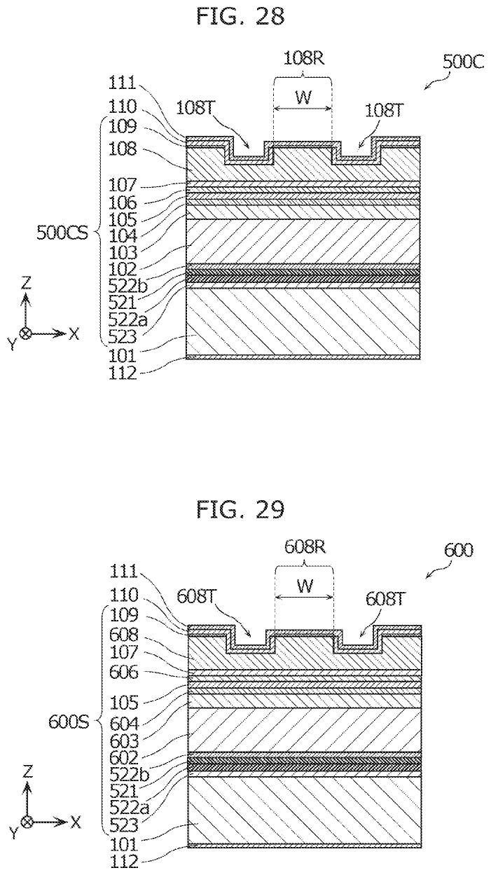

A nitride semiconductor light-emitting element according to Variation 3 of Embodiment 5 will be described. The nitride semiconductor light-emitting element according to the present variation differs from nitride semiconductor light-emitting element 500B according to Variation 2 of Embodiment 5 in regard to the additional inclusion of second buffer layers. Hereinafter, the nitride semiconductor light-emitting element according to the present variation will be described with reference to FIG. 28, focusing on the difference from nitride semiconductor light-emitting element 500B according to Variation 2 of Embodiment 5.

FIG. 28 is a schematic cross-sectional view of the overall configuration of nitride semiconductor light-emitting element 500C according to the present variation. As illustrated in FIG. 28, nitride semiconductor light-emitting element 500C according to the present variation includes substrate 101, semiconductor stack 500CS, current blocking layer 110, P-side electrode 111, and N-side electrode 112. Semiconductor stack 500CS includes third buffer layer 523, first buffer layer 521, second buffer layers 522a and 522b, N-type cladding layer 102, N-side first guide layer 103, N-side second guide layer 104, active layer 105, P-side first guide layer 106, electron barrier layer 107, P-type cladding layer 108, and contact layer 109.

In the present variation, second buffer layer 522a is disposed between third buffer layer 523 and first buffer layer 521. Second buffer layer 522b is disposed between first buffer layer 521 and N-type cladding layer 102.

With such a configuration, nitride semiconductor light-emitting element 500C according to the present variation produces the same advantageous effects as nitride semiconductor light-emitting element 500B according to Variation 2 of Embodiment 5. In addition, owing to the inclusion of second buffer layers 522a and 522b, nitride semiconductor light-emitting element 500C according to the present variation produces the same advantageous effects as nitride semiconductor light-emitting element 500A according to Variation 1 of Embodiment 5.

In the present variation, it is possible to achieve nitride semiconductor light-emitting element 500C where the effective refractive index difference ΔN is 7.4×10⁻³, peak position PS1 of the light intensity distribution in the stacking direction at the portion below ridge 108R is 96.0 nm, the peak position difference ΔP is −26.3 nm, the optical confinement factor of active layer 105 is 1.69%, and waveguide loss is 4.65 cm⁻¹, as is the case of nitride semiconductor light-emitting element 500 according to Embodiment 5.

### Variation 4 of Embodiment 5

A nitride semiconductor light-emitting element according to Variation 4 of Embodiment 5 will be described. The nitride light emitting element according to the present variation differs from nitride semiconductor light-emitting element 500C according to Variation 3 of Embodiment 5 in regard to the composition of each of the layers in the semiconductor stack. Hereinafter, the nitride semiconductor light-emitting element according to the present variation will be described, focusing on the difference from nitride semiconductor light-emitting element 500C according to Variation 3 of Embodiment 5.

The nitride semiconductor light-emitting element according to the present variation includes substrate 101, a semiconductor stack, current blocking layer 110, P-side electrode 111, and N-side electrode 112, like nitride semiconductor light-emitting element 500C according to Variation 3 of Embodiment 5. The semiconductor stack includes a third buffer layer, a first buffer layer, two second buffer layers, an N-type cladding layer, an N-side first guide layer, an N-side second guide layer, an active layer, a P-side first guide layer, an electron barrier layer, a P-type cladding layer, and a contact layer.

The third buffer layer according to the present variation is an N-type Al_{0.02}Ga_{0.98}N layer with a thickness of 1000 nm. The third buffer layer is doped with Si at a concentration of 1×10¹⁸ cm⁻³ as an impurity.

The first buffer layer according to the present variation is an N-type In_{0.04}Ga_{0.96}N layer with a thickness of 150 nm. The first buffer layer is doped with Si at a concentration of 1×10¹⁸ cm⁻³ as an impurity.

Each of the two second buffer layers according to the present variation is an N-type GaN layer with a thickness of 10 nm. Each of the two second buffer layers is doped with Si at a concentration of 1×10¹⁸ cm⁻³ as an impurity.

The N-type cladding layer according to the present variation is an N-type Al_{0.065}Ga_{0.935}N layer with a thickness of 540 nm. The N-type cladding layer is doped with Si at a concentration of 1×10¹⁸ cm⁻³ as an impurity.

The N-side first guide layer according to the present variation is an N-type Al_{0.03}Ga_{0.97}N layer with a thickness of 100 nm. The N-side first guide layer is doped with Si at a concentration of 1×10¹⁸ cm⁻³ as an impurity.

The N-side second guide layer according to the present variation is an undoped Al_{0.02}Ga_{0.98}N layer with a thickness of 120 nm.

The active layer according to the present variation includes two barrier layers and a well layer disposed between the two barrier layers, like the active layer according to Variation 3 of Embodiment 5.

Each of the two barrier layers according to the present variation is an undoped Al_{0.04}Ga_{0.96}N layer with a thickness of 12 nm.

The well layer according to the present variation is an undoped Al_{0.078}Ga_{0.892}In_{0.03}N layer with a thickness of 17.5 nm

The P-side first guide layer according to the present variation is a P-type Al_{0.035}Ga_{0.965}N layer with a thickness of 200 nm. The P-side first guide layer is doped with Mg at a concentration of 1×10¹⁸ cm⁻³ as an impurity.

The electron barrier layer, the P-type cladding layer, and the contact layer according to the present variation have the same configurations as electron barrier layer 107, P-type cladding layer 108, and contact layer 109 according to Variation 3 of Embodiment 5, respectively.

In the nitride semiconductor light-emitting element having the above configuration, since each of the layers disposed between the N-type cladding layer and the P-type cladding layer, excluding the well layer, has a refractive index lower than the refractive index of GaN, the effective refractive index in the region in which light propagating in the waveguide is distributed is lower than the effective refractive index of substrate 101 made of GaN. In addition, since the wavelength corresponding to the band gap energy of GaN is approximately 365 nm, substrate 101 transmits a laser beam in the 375 nm wavelength band.

As a result, light that has reached substrate 101 is spread over the entire substrate 101 without being attenuated at substrate 101, and waveguide loss increases.

As a method of reducing the proportion of such light that reaches substrate 101, increasing the thickness of the N-type cladding layer is conceivable. In this case, however, a tensile strain imposed by the semiconductor stack increases. Therefore, after the crystal growth of the semiconductor stack on base material 101M of substrate 101, base material 101M on which the semiconductor stack is formed is prone to crack due to a temperature change in various processing processes for forming a laser element including the semiconductor stack.

It is therefore necessary to set the thickness of the N-type cladding layer having a high Al composition ratio to, for example, 1 μm or less. In the present variation, the thickness of the N-type cladding layer is set to 540 nm to inhibit an increase in the tensile strain. In this case, since light attenuation in the N-type cladding layer is not sufficient, the first buffer layer which is an N-type InGaN buffer layer with an In composition ratio of 0.04 is disposed below the N-type cladding layer in order to attenuate light by absorption.

Although the In composition ratio of first buffer layer 521 is 0.05 in Variation 3 of Embodiment 5, the In composition ratio of the first buffer layer according to the present variation is 0.04 and is lower than the In composition ratio of first buffer layer 521 according to Variation 3 of Embodiment 5. If the In composition ratio of the first buffer layer is increased, the absorption of a laser beam in this layer increases, making it possible to increase light attenuation, but pits are prone to occur in the first buffer layer. If the In composition ratio of the first buffer layer is low, however, light absorption in this layer decreases, and this makes it easier for light to reach substrate 101 without being attenuated too much in the first buffer layer.

In view of this, in a buffer layer structure according to the present variation, by setting the Al composition ratio of the third buffer layer made of N-type AlGaN to 0.02 that is higher than the Al composition ratio 0.007 of third buffer layer 523 according to Variation 3 of Embodiment 5, the refractive index of the third buffer layer is reduced and light attenuation in this layer is increased. As a result, in the buffer layer structure according to the present variation, a tensile strain from the third buffer layer increases, but the light distribution intensity of light that reaches substrate 101 can be inhibited while the occurrence of pits in the first buffer layer is inhibited.

When the In composition ratio of the first buffer layer is set to be lower than 0.05, the effect of attenuating light in this layer decreases. In view of this, it is necessary to increase the Al composition ratio of the third buffer layer to be higher than 0.01 and reduce the refractive index of the third buffer layer to increase light attenuation so that the light intensity of light that reaches substrate 101 decreases. However, if the Al composition ratio of the third buffer layer is increased too much, the tensile strain from the third buffer layer increases too much. It is therefore necessary to set the Al composition ratio of the third buffer layer to one third (33.3%) or less of the average Al composition ratio of the N-type cladding layer made of N-type AlGaN. In the present variation, the Al composition ratio of the third buffer layer is 30.7% of the Al composition ratio 0.065 of the N-type cladding layer.

If the In composition ratio of the first buffer layer is reduced too much, the light attenuation effect in this layer decreases and a compressive strain from the first buffer layer decreases. The following effects of the first buffer layer therefore decrease: compensating a tensile strain from the N-type cladding layer and the P-type cladding layer each of which has a high Al composition ratio and imposes a large tensile strain, and reducing the bow of the wafer after crystal growth. For this reason, the In composition ratio of the first buffer layer may be 0.03 or more.

When the In composition ratio of the first buffer layer is 0.05 or more, there is no need to increase the Al composition ratio of the third buffer layer since the light attenuation effect owing to light absorption in this layer can be increased. Owing to the third buffer being an AlGaN layer with an Al composition ratio of 0.01 or less, the flatness of the first buffer layer surface during crystal growth can be improved. In addition, the bow of base material 101M of substrate 101 can be reduced by reducing the tensile strain imposed by the third buffer layer.

Next, the Al composition ratio of each of the guide layers according to the present variation will be described.

The Al composition ratio of the N-side first guide layer is 0.03, the Al composition ratio of the N-side second guide layer is 0.02, and the Al composition ratio of the P-side first guide layer is 0.035. In the present variation, the average refractive index of the N-side first guide layer and the N-side second guide layer is higher than the refractive index of the P-side first guide layer, and the refractive index of the N-side second guide layer is higher than the refractive index of the N-side first guide layer. This makes it possible to enhance the controllability of positioning, in the vicinity of the well layer, peak position PS1 of the light intensity distribution in the stacking direction.

Next, the well layer according to the present variation will be described.

Owing to the well layer being an AlGaInN layer including Al, which is the case in the present variation, the In composition ratio of the well layer for obtaining laser oscillation in the 375 nm band can be increased more compared to the In composition ratio corresponding to when the well layer is an InGaN layer. By setting the In composition ratio of 0.03 and the Al composition ratio of 0.047 for the well layer according to the present variation, laser oscillation in the 375 nm wavelength band can be obtained in the nitride semiconductor light-emitting element. The In composition ratio can be thus increased to 0.03 compared to the In composition ratio of 0.01 with which laser oscillation light in the 375 nm band can be obtained when the well layer is an InGaN layer. When the In composition ratio of the well layer is 0.05, laser oscillation in the 375 nm wavelength band can be obtained in the nitride semiconductor light-emitting element by setting the Al composition ratio of the well layer to 0.093.

As a result of increasing the In composition ratio of the well layer by using an AlGaInN layer including Al for the well layer, a compressive strain from the well layer increases. In this case, since a tensile strain accumulated in the N-type cladding layer, the N-side first guide layer, and the N-side second guide layer can be compensated with the compressive strain from the well layer, the occurrence of cracks in the wafer can be inhibited. In addition, since the compressive strain from the well layer increases, a difference in the energy level of the base status between heavy holes and light holes formed in the well layer increases, and the carrier density of the heavy holes present at the base level increases. The amplification gain of the active layer therefore increases with the little amount of injected current, and the oscillation current threshold can be reduced.

When x denotes the Al composition ratio of the well layer and y denotes the In composition ratio of the well layer, where 0≤x≤1 and 0≤y≤1, it is possible to obtain, with the nitride semiconductor light-emitting element, laser oscillation light in the 375 nm wavelength band in the UV range by defining each of the composition ratios x and y to satisfy the following relationships.

2.34y≥x≥2.34y−0.234

y≥0.234

The lattice constants of AlN, GaN, and InN composing AlGaInN in an a-axis direction are 3.08 Å, 3.16 Å, and 3.5 Å, respectively, and the lattice constant of InN is greater than the lattice constants of AlN and GaN. For this reason, the sum of internal strain energies generated due to a difference from a stable atomic spacing based on the lattice constant difference between each of three family atoms (Al, Ga, and In) and a nitride atom decreases more when In atoms in the AlGaInN layer are locally segregated and unevenly distributed than when the In atoms are evenly distributed in the crystal growth surface. Since the lattice constant difference between AlN and GaN is small, unevenness in the Al atom distribution is less than unevenness in the In atom distribution.

As a result, if the In composition ratio of the AlGaN layer is increased, a high In composition region with an average radius in the range of several nanometers to tens of nanometers and a locally high In composition ratio can be easily formed in the growth surface. The high In composition region has a small band gap energy and functions as a quantum dot active layer. When a quantum dot region is formed, a quantum level is formed not only in the stacking direction (growth layer direction) but also in the growth layer in-plane direction, and it is thus possible to increase the densities of electrons and holes present at the base level of the quantum level. The oscillation threshold (oscillation current threshold) of the nitride semiconductor light-emitting element can be therefore reduced.

In a semiconductor laser element with the 375 nm wavelength band, a difference in a band gap energy between a guide layer and a well layer is small, and electrons injected to the well layer are prone to leak to the P-side first guide layer. Using a four-dimensional AlGaInN well layer can therefore reduce the oscillation threshold and reduce the leakage of the electrons, thereby improving the temperature characteristics of the nitride semiconductor light-emitting element.

### Embodiment 6

A nitride semiconductor light-emitting element according to Embodiment 6 will be described. The nitride semiconductor light-emitting element according to the present embodiment differs from nitride semiconductor light-emitting element 500C according to Variation 3 of Embodiment 5 in regard mainly to an increase in the Al composition ratio of each of the cladding layers. Hereinafter, the nitride semiconductor light-emitting element according to the present embodiment will be described with reference to FIG. 29, focusing on the difference from nitride semiconductor light-emitting element 500C according to Variation 3 of Embodiment 5.

FIG. 29 is a schematic cross-sectional view of the overall configuration of nitride semiconductor light-emitting element 600 according to the present embodiment. As illustrated in FIG. 29, nitride semiconductor light-emitting element 600 according to the present embodiment includes substrate 101, semiconductor stack 600S, current blocking layer 110, P-side electrode 111, and N-side electrode 112. Semiconductor stack 600S includes third buffer layer 523, first buffer layer 521, second buffer layers 522a and 522b, N-type cladding layer 602, N-side first guide layer 603, N-side second guide layer 604, active layer 105, P-side first guide layer 606, electron barrier layer 107, P-type cladding layer 608, and contact layer 109.

N-type cladding layer 602 is an N-type Al_{0.11}Ga_{0.89}N layer with a thickness of 540 nm. N-type cladding layer 602 is doped with Si at a concentration of 5×10¹⁷ cm⁻³ as an impurity.

N-side first guide layer 603 is an N-type Al_{0.06}Ga_{0.94}N layer with a thickness of 100 nm. N-side first guide layer 603 is doped with Si at a concentration of 5×10¹⁷ cm⁻³ as an impurity.

N-side second guide layer 604 is an undoped Al_{0.04}Ga_{0.96}N layer with a thickness of 120 nm.

P-side first guide layer 606 is a P-type Al_{0.08}Ga_{0.92}N layer with a thickness of 200 nm. P-side first guide layer 606 is doped with Mg at a concentration of 1×10¹⁸ cm⁻³ as an impurity.

P-type cladding layer 608 is a P-type Al_{0.11}Ga_{0.89}N layer with a thickness of 450 nm. P-type cladding layer 608 is doped with Mg as an impurity. P-type cladding layer 608 includes a low-concentration region located lower than the vertical center of P-type cladding layer 608 (i.e., on the side closer to active layer 105) and having an impurity concentration lower than the impurity concentration of the remainder of P-type cladding layer 608. Specifically, P-type cladding layer 608 includes: a P-type Al_{0.11}Ga_{0.89}N layer with a thickness of 150 nm which is disposed in the lower portion of P-type cladding layer 608 and is doped with Mg at a concentration of 2×10¹⁸ cm⁻³; and a P-type Al_{0.11}Ga_{0.89}N layer with a thickness of 300 nm which is disposed in the upper portion of P-type cladding layer 608 (i.e., on the side farther from active layer 105) and is doped with Mg at a concentration of 1×10¹⁹ cm⁻³.

Ridge 608R is formed in P-type cladding layer 608. Two trenches 608T disposed along ridge 608R and extending in the Y-axis direction are also formed in P-type cladding layer 608.

As described above, in the present embodiment, by increasing the Al composition ratios of N-type cladding layer 602 and P-type cladding layer 608, the refractive indices of N-type cladding layer 602 and P-type cladding layer 608 can be reduced. Therefore, in the present embodiment, it is possible to reduce waveguide loss and increase the optical confinement factor. Moreover, peak position PS1 of the light intensity distribution in the stacking direction in the portion below ridge 608R and the peak position difference ΔP can be both reduced. As a result, temperature characteristics and IL characteristics with excellent linearity can be achieved.

According to the present embodiment, it is possible to achieve nitride semiconductor light-emitting element 600 where the effective refractive index difference ΔN is 4.8×10⁻³, peak position PS1 of the light intensity distribution in the stacking direction at the portion below ridge 608R is 6.9 nm, the peak position difference ΔP is −3.3 nm, the optical confinement factor of active layer 105 is 5.3%, and waveguide loss is 4.0 cm⁻¹.

### Embodiment 7

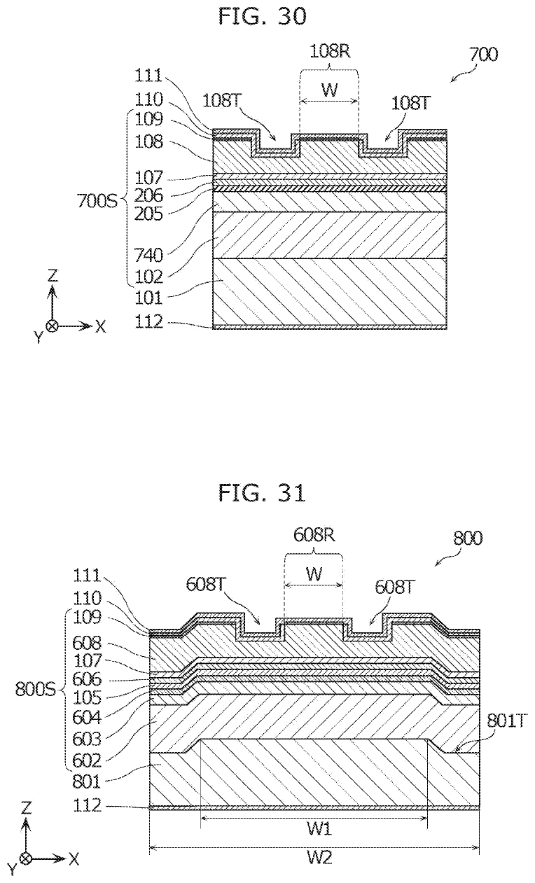

A nitride semiconductor light-emitting element according to Embodiment 7 will be described. The nitride semiconductor light-emitting element according to the present embodiment differs from nitride semiconductor light-emitting element 200 according to Embodiment 2 in regard to the configuration of the N-side guide layer. Hereinafter, the nitride semiconductor light-emitting element according to the present embodiment will be described with reference to FIG. 30, focusing on the difference from nitride semiconductor light-emitting element 200 according to Embodiment 2.

FIG. 30 is a schematic cross-sectional view of the overall configuration of nitride semiconductor light-emitting element 700 according to the present embodiment. As illustrated in FIG. 30, nitride semiconductor light-emitting element 700 according to the present embodiment includes substrate 101, semiconductor stack 700S, current blocking layer 110, P-side electrode 111, and N-side electrode 112. Semiconductor stack 700S includes N-type cladding layer 102, N-side guide layer 740, active layer 205, P-side first guide layer 206, electron barrier layer 107, P-type cladding layer 108, and contact layer 109.

N-side guide layer 740 according to the present embodiment is an optical guide layer disposed above N-type cladding layer 102. The composition of N-side guide layer 740 is not uniform in the stacking direction. Specifically, N-side guide layer 740 is an N-type AlGaN layer with a thickness of 220 nm. The Al composition ratio of N-side guide layer 740 changes from 0.03 to 0.02 from the lower portion toward the upper portion in the stacking direction. How the Al composition ratio changes is not specifically limited. In the present embodiment, the Al composition ratio of N-side guide layer 740 changes at a constant rate of change in the stacking direction. The lower portion of N-side guide layer 740 with a thickness of 100 nm is doped with Si at a concentration of 5×10¹⁷ cm⁻³ as an impurity. The upper portion of N-side guide layer 740 with a thickness of 100 nm is not doped with an impurity.

The band gap energy of N-type cladding layer 102 is thus larger than the average band gap energy of N-side guide layer 740. The average refractive index of N-side guide layer 740 is therefore higher than the average refractive index of N-type cladding layer 102, and N-side guide layer 740 therefore functions as an optical guide layer. The band gap energy of each of barrier layers 105 and 105c is larger than the average band gap energy of N-side guide layer 740. In other words, the refractive index of each of barrier layers 105a and 105c is lower than the average refractive index of N-side guide layer 740. Therefore, the peak position of the light intensity distribution can be brought closer to active layer 205, as is the case of nitride semiconductor light-emitting element 100 according to Embodiment 1.

The band gap energy of the lower end portion of N-side guide layer 740 (the end portion closer to N-type cladding layer 102) is larger than the band gap energy of the upper end portion (the end portion closer to active layer 205) of N-side guide layer 740. In the present embodiment, the band gap energy of the upper end portion of N-side guide layer 740, which is a guide layer closer to barrier layer 105a, is smaller than the band gap energy of barrier layer 105a. In other words, the refractive index of the upper end portion of N-side guide layer 740, which is the guide layer closer to barrier layer 105a, is higher than the refractive index of barrier layer 105a. The refractive index of the upper end portion of N-side guide layer 740, which is closer to active layer 205 than the lower end portion of N-side guide layer 740 is, is higher than the refractive index of the lower end portion of N-side guide layer 740. Owing to semiconductor stack 700S having such a refractive index distribution, the light intensity distribution can be shifted in a direction toward the upper end portion of N-side guide layer 740, as is the case of nitride semiconductor light-emitting element 100 according to Embodiment 1. In addition, since active layer 205 is not doped with an impurity, positioning the peak position of the light intensity distribution in the vicinity of active layer 205 can reduce waveguide loss caused by light absorption due to an impurity.

The band gap energy of P-type cladding layer 108 is larger than the band gap energy of P-side first guide layer 206. The band gap energy of P-side first guide layer 206 is larger than the average band gap energy of N-side guide layer 740. In other words, the refractive index of P-side first guide layer 206 is lower than the average refractive index of N-side guide layer 740. This makes it possible to shift the peak position of the light intensity distribution in the direction from P-side first guide layer 206 to N-side guide layer 740 (i.e., downward). Therefore, in the present embodiment, the peak position of the light intensity distribution can be brought closer to active layer 205, as is the case of nitride semiconductor light-emitting element 100 according to Embodiment 1.

### Embodiment 8

A nitride semiconductor light-emitting element according to Embodiment 8 will be described. The nitride semiconductor light-emitting element according to the present embodiment differs from nitride semiconductor light-emitting element 600 according to Embodiment 6 in that isolation trenches are formed in the substrate and the buffer layers are not included. Hereinafter, the nitride semiconductor light-emitting element according to the present embodiment will be described with reference to FIG. 31, focusing on the difference from nitride semiconductor light-emitting element 600 according to Embodiment 6.

FIG. 31 is a schematic cross-sectional view of the overall configuration of nitride semiconductor light-emitting element 800 according to the present embodiment. As illustrated in FIG. 31, nitride semiconductor light-emitting element 800 according to the present embodiment includes substrate 801, semiconductor stack 800S, current blocking layer 110, P-side electrode 111, and N-side electrode 112. Semiconductor stack 800S includes N-type cladding layer 602, N-side first guide layer 603, N-side second guide layer 604, active layer 105, P-side first guide layer 606, electron barrier layer 107, P-type cladding layer 608, and contact layer 109.

Substrate 801 is a substrate made of GaN. A plurality of isolation trenches 801T are formed in substrate 801. In the present embodiment, isolation trenches 801T are formed along ridge 608R in the upper principal surface of substrate 801.

Semiconductor stack 800S is stacked on the plurality of isolation trenches 801T. In other words, N-type cladding layer 602, N-side first guide layer 603, N-side second guide layer 604, active layer 105, P-side first guide layer 606, electron barrier layer 107, P-type cladding layer 608, and contact layer 109 are stacked on the plurality of isolation trenches 801T.

By thus forming isolation trenches 801T in substrate 801 and stacking semiconductor stack 800S on isolation trenches 801T, width W2 of nitride semiconductor light-emitting element 800 can be effectively reduced to distance W1 between isolation trenches 801T. Since semiconductor stack 800S stacked on substrate 801 includes N-type cladding layer 602 and P-type cladding layer 608 each having a relatively high Al composition ratio, a tensile strain on substrate 801 made of GaN is generated.

Since P-type cladding layer 608 is located farther from substrate 801 than N-type cladding layer 602 is, the lattice constant of P-type cladding layer 608 is more prone to change to a lattice constant value that is in accordance with an atomic composition, compared to the lattice constant of N-type cladding layer 602. Sheer stress in the direction in which P-type cladding layer 608 shrinks in the horizontal direction is therefore applied to semiconductor stack 800S formed on the edge portion of isolation trench 801T that is closer to ridge 608R.

An influence that this sheer stress has on the region sandwiched between two adjacent isolation trenches 801T is large when distance W1 is short. Therefore, when distance W1 is short, tensile stress in P-type cladding layer 608 decreases and the base material of substrate 801 hardly cracks after semiconductor stack 800S is stacked on the base material. Therefore, distance W1 may be, for example, 2500 μm or less.

When distance W1 is too short, however, the thermal resistance of nitride semiconductor light-emitting element 800 increases. Distance W1 may be therefore 1000 μm or more.

When width W2 of nitride semiconductor light-emitting element 800 including two isolation trenches 801T is too small, the thermal resistance of nitride semiconductor light-emitting element 800 increases. When separating, along the resonator direction, each of a plurality of nitride semiconductor light-emitting elements 800 which are mutually connected in an array when formed, it is difficult to separate each of the plurality of nitride semiconductor light-emitting elements 800 because processing properties deteriorate. Therefore, width W2 may be 150 μm or more. When width W2 is too large, the effect of reducing the thermal resistance value of nitride semiconductor light-emitting element 800 decreases. Therefore, width W2 may be 400 μm or less.

When the difference between distance W1 and width W2 is reduced too much, scattered debris are likely to adhere to the lateral walls of nitride semiconductor light-emitting element 800 in the separation process of separating, along the resonator direction, each of the plurality of nitride semiconductor light-emitting elements 800 formed in an array. Due to such debris, there is an increasing risk of generating leak current when nitride semiconductor light-emitting element 800 is mounted junction-down. Therefore, the difference between distance W1 and width W2 (W2−W1) may be 8 μm or more.

Since a region in which sheer stress occurs gets longer, as the depth of isolation trench 801T increases, in semiconductor stack 800S formed on the edge portion of isolation trench 801T that is closer to ridge 608R, the above-mentioned effect of inhibiting the cracks increases. The depth of isolation trench 801T may be at least the thickness from N-type cladding layer 602 to N-type cladding layer 109 (i.e., at least the distance from the lower end of N-type cladding layer 602 to the upper end of contact layer 109) in semiconductor stack 800S.

As described above, even when the Al composition ratio of each of the cladding layers is 8% or more, as is the case in the present embodiment, it is possible, by forming isolation trenches 801T in substrate 801, to inhibit the base material of substrate 801 from cracking after the crystal growth of semiconductor stack 800S.

### Embodiment 9

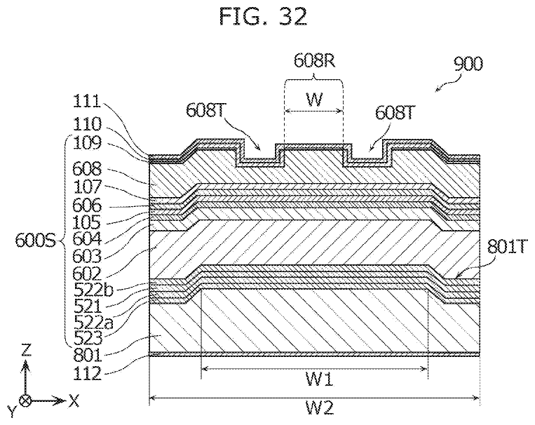

A nitride semiconductor light-emitting element according to Embodiment 9 will be described. The nitride semiconductor light-emitting element according to the present embodiment differs from nitride semiconductor light-emitting element 800 according to Embodiment 8 in regard to the inclusion of buffer layers. Hereinafter, the nitride semiconductor light-emitting element according to the present embodiment will be described with reference to FIG. 32, focusing on the difference from nitride semiconductor light-emitting element 800 according to Embodiment 8.

FIG. 32 is a schematic cross-sectional view of the overall configuration of nitride semiconductor light-emitting element 900 according to the present embodiment. As illustrated in FIG. 32, nitride semiconductor light-emitting element 900 according to the present embodiment includes substrate 801, semiconductor stack 600S, current blocking layer 110, P-side electrode 111, and N-side electrode 112. Semiconductor stack 600S includes third buffer layer 523, first buffer layer 521, second buffer layers 522a and 522b, N-type cladding layer 602, N-side first guide layer 603, N-side second guide layer 604, active layer 105, P-side first guide layer 606, electron barrier layer 107, P-type cladding layer 608, and contact layer 109.

A plurality of isolation trenches 801T are formed also on substrate 801 according to the present embodiment. Therefore, nitride semiconductor light-emitting element 900 according to the present embodiment produces the same advantageous effects as nitride semiconductor light-emitting element 800 according to Embodiment 8.

Since semiconductor stack 600S according to the present embodiment includes first buffer layer 521, second buffer layers 522a and 522b, and third buffer layer 523, nitride semiconductor light-emitting element 900 according to the present embodiment produces also the same advantageous effects as nitride semiconductor light-emitting element 600 according to Embodiment 6.

### Variations, etc.

Although the nitride semiconductor light-emitting element according to the present disclosure has been described based on each of the embodiments so far, the present disclosure is not limited to the embodiments.

For example, in each of the embodiments, the Al composition ratio of the electron barrier layer is uniform in the layer, but the electron barrier layer may include a region in which the Al composition ratio gradually increases from the lower portion of the region toward the upper portion of the region (i.e., with increasing proximity to the P-type cladding layer). The configuration in which the Al composition ratio monotonically increases includes a configuration including a region in which the Al composition ratio is constant in the stacking direction. For example, the configuration in which the Al composition ratio monotonically increases includes a configuration in which the Al composition ratio increases in steps. For example, the electron barrier layer may include: an Al composition variation region in which the Al composition ratio monotonically increases with increasing proximity to the P-type cladding layer in the stacking direction; and an Al composition constant region in which the Al composition ratio is constant in the stacking direction. The Al composition variation region is disposed, for example, at the end portion of the electron barrier layer that is closer to the active layer, and the Al composition constant region is disposed at the end portion of the electron barrier layer that is closer to the P-type cladding layer. In the Al composition variation region, the Al composition ratio monotonically increases at a constant rate of change with increasing proximity to the P-type cladding layer in the stacking direction. More specifically, the Al composition variation region has a thickness of 3 nm and the composition near the interface closer to the active layer is Al_{0.04}Ga_{0.96}N, and the Al composition ratio monotonically increases with increasing proximity to the Al composition constant region such that the composition near the interface with the Al composition constant region is Al_{0.36}Ga_{0.64}N. The Al composition constant region has a thickness of 2 nm and the composition of the entire region is Al_{0.36}Ga_{0.64}N. The electron barrier layer is doped with Mg at a concentration of 1×10¹⁹ cm⁻³ as an impurity.

Owing to the electron barrier layer including an Al composition variation region in which the Al composition ratio monotonically increases, the electric potential barrier in the valence band of the electron barrier layer can be reduced more so than when the Al composition ratio is uniform. Therefore, holes can easily flow from the P-type cladding layer to the active layer. It is therefore possible to inhibit an increase in the electrical resistance of the nitride semiconductor light-emitting element. This makes it possible to reduce the operating voltage of the nitride semiconductor light-emitting element. Moreover, since self-heating during operation of the nitride semiconductor light-emitting element can be reduced, the temperature characteristics of the nitride semiconductor light-emitting element can be improved. High-power operation of the nitride semiconductor light-emitting element is thus possible.

In each of the embodiments, the Al composition ratio of the N-type cladding layer and the Al composition ratio of the P-type cladding layer are same, but do not necessarily need to be same. For example, the Al composition ratio of the N-type cladding layer may be lower than the Al composition ratio of the P-type cladding layer. This allows the refractive index of the N-type cladding layer to be higher than the refractive index of the P-type cladding layer, and the light intensity distribution in the stacking direction can be therefore shifted in a direction toward the N-type cladding layer. The N-type cladding layer and the P-type cladding layer may be each, for example, a superlattice layer composed of multilayer films including a GaN thin film and an AlGaN thin film. In this case, the Al composition ratio of each of the cladding layers is the average Al composition ratio of the entire superlattice layer.

For example, each of the embodiments gives an example in which the nitride semiconductor light-emitting element is a semiconductor laser element, but the nitride semiconductor light-emitting element is not limited to a semiconductor laser element. The nitride semiconductor light-emitting element may be, for example, a super luminescent diode. In such cases, the reflectance of the end face of the semiconductor stack included in the nitride semiconductor light-emitting element with respect to the light emitted from the semiconductor stack may be 0.1% or less. Such a reflectance can be achieved by, for example, forming, on the end face, an anti-reflective film including, for instance, a dielectric multilayer film. Alternatively, if the ridge that serves as the waveguide is inclined at an angle of 5° or more from the normal direction of the front end face and intersects the front end face in an inclined stripe structure, the ratio of the component of guided light that reflected off the front end face and combines with the waveguide to become guided light again can be reduced to a small value of 0.1% or less.

In the nitride semiconductor light-emitting element according to each of the embodiments, active layer 105 has a structure including a single well layer, but may have a structure including a plurality of well layers.

The nitride semiconductor light-emitting element according to each of the embodiments is exemplified as including electron barrier layer 107 and current blocking layer 110, but the nitride semiconductor light-emitting element does not necessarily need to include these layers.

In the nitride semiconductor light-emitting element according to each of the embodiments, at least one of the barrier layer, the N-side guide layer (the N-side first guide layer or the N-side second guide layer), the P-side first guide layer and the P-side second guide layer, or the N-type cladding layer may be formed using AlGaInN. Since at least part of a tensile strain on the semiconductor stack can be canceled by using AlGaInN, cracks can be reduced. Particularly by using, as AlGaInN, AlGaInN that generates a compressive strain, the effect of canceling the tensile strain on the semiconductor stack increases. It is conceivable to use AlGaInN, which generates a compressive strain, only for the N-side guide layer (the N-side first guide layer, the N-side second guide layer, for instance) and use AlGaN for other layers (the barrier layer, the P-side guide layer, and the N-type cladding layer).

Various modifications of the above embodiments that may be conceived by those skilled in the art, as well as embodiments resulting from arbitrary combinations of elements and functions from different embodiments that do not depart from the essence of the present disclosure are also included in the present disclosure.

### INDUSTRIAL APPLICABILITY

The nitride semiconductor light-emitting element according to the present disclosure can be applied to, for example, a light source for processing machines, as a high-output, high-efficiency light source.

1. A nitride semiconductor light-emitting element comprising:
an N-type cladding layer;
an N-side first guide layer disposed above the N-type cladding layer;
an N-side second guide layer disposed above the N-side first guide layer;
an active layer disposed above the N-side second guide layer and including a well layer and a barrier layer; and
a P-type cladding layer disposed above the active layer, wherein a band gap energy of the barrier layer is larger than a band gap energy of the N-side second guide layer,
the band gap energy of the N-side second guide layer is smaller than a band gap energy of the N-side first guide layer,
the band gap energy of the N-side first guide layer is smaller than a band gap energy of the N-type cladding layer, and
the N-type cladding layer, the N-side first guide layer, the N-side second guide layer, the barrier layer, and the P-type cladding layer each comprise a nitride semiconductor including Al.

2. The nitride semiconductor light-emitting element according to claim 1, wherein
the band gap energy of the barrier layer is larger than an average band gap energy of the N-side first guide layer and the N-side second guide layer.

3. The nitride semiconductor light-emitting element according to claim 1, wherein
the barrier layer comprises Al_{b}Ga_{1-b}N where 0<b≤1.

4. The nitride semiconductor light-emitting element according to claim 1, wherein
the N-side first guide layer comprises Al_{Xn1}Ga_{1-Xn1}N where 0<Xn1≤1.

5. The nitride semiconductor light-emitting element according to claim 1, wherein
the N-side second guide layer comprises Al_{Xn2}Ga_{1-Xn2}N where 0≤Xn2≤1.

6. The nitride semiconductor light-emitting element according to claim 1, wherein
a thickness of the N-side second guide layer is greater than a thickness of the N-side first guide layer.

7. The nitride semiconductor light-emitting element according to claim 1, wherein
an impurity concentration of the N-side first guide layer is higher than an impurity concentration of the N-side second guide layer.

8. The nitride semiconductor light-emitting element according to claim 1, further comprising:
a P-side electrode disposed above the P-type cladding layer, wherein
the P-side electrode includes Ag.

9. A nitride semiconductor light-emitting element comprising:
an N-type cladding layer;
an N-side guide layer disposed above the N-type cladding layer;
an active layer disposed above the N-side guide layer and including a well layer and a barrier layer;
a P-type cladding layer disposed above the active layer;
a P-side first guide layer disposed between the active layer and the P-type cladding layer; and
an electron barrier layer disposed between the P-side first guide layer and the P-type cladding layer, wherein
a band gap energy of the barrier layer is larger than an average band gap energy of the N-side guide layer,
a band gap energy of the N-type cladding layer is larger than the average band gap energy of the N-side guide layer,
a band gap energy of the N-side guide layer is larger in a lower end portion of the N-side guide layer than in an upper end portion of the N-side guide layer,
a band gap energy of the P-type cladding layer is larger than a band gap energy of the P-side first guide layer,
the band gap energy of the P-side first guide layer is larger than the average band gap energy of the N-side guide layer, and
the N-type cladding layer, the N-side guide layer, the barrier layer, the P-type cladding layer, the P-side first guide layer, and the electron barrier layer each comprise a nitride semiconductor including Al.

10. The nitride semiconductor light-emitting element according to claim 9, wherein
the N-type cladding layer comprises Al_{Xnc}Ga_{1-Xnc}N,
the N-side guide layer comprises AlGaN,
the barrier layer comprises Al_{b}Ga_{1-b}N,
the P-side first guide layer comprises AlGaN,
the electron barrier layer comprises Al_{Xd}Ga_{1-Xd}N,
the P-type cladding layer comprises Al_{Xpc}Ga_{1-Xpc}N, and
the following relationships hold true:
b>Xg3,
Xp1≥Xn,
Xnc>Xn, and
Xpc>Xp1, where Xn denotes an average Al composition ratio of the N-side guide layer and Xp1 denotes an average Al composition ratio of the P-side first guide layer.

11. The nitride semiconductor light-emitting element according to claim 10, wherein
the N-side guide layer includes: an N-side first guide layer that comprises AlGaN; and an N-side second guide layer that is disposed between the N-side first guide layer and the active layer and comprises AlGaN, and
the following relationship holds true:
Xn1>Xn2 where Xn1 denotes an Al composition ratio of the N-side first guide layer and Xn2 denotes an Al composition ratio of the N-side second guide layer.

12. The nitride semiconductor light-emitting element according to claim 11, wherein
a thickness of the N-side second guide layer is greater than a thickness of the N-side first guide layer.

13. The nitride semiconductor light-emitting element according to claim 9, wherein
the electron barrier layer includes a region in which an Al composition ratio gradually increases from a lower portion of the region toward an upper portion of the region.

14. The nitride semiconductor light-emitting element according to claim 9, wherein
the P-type cladding layer includes a low-concentration region located lower than a vertical center of the P-type cladding layer and having a lower impurity concentration than a remainder of the P-type cladding layer.

15. The nitride semiconductor light-emitting element according to claim 9, wherein
an Al composition ratio Xnc of the N-type cladding layer is lower than an Al composition ratio Xpc of the P-type cladding layer.

16. The nitride semiconductor light-emitting element according to claim 9, wherein
a thickness of the well layer is 10 nm or more.

17. The nitride semiconductor light-emitting element according to claim 1, wherein
the N-type cladding layer is stacked above a substrate that comprises GaN.

18. The nitride semiconductor light-emitting element according to claim 17, further comprising:
a first buffer layer disposed between the substrate and the N-type cladding layer and including In.

19. The nitride semiconductor light-emitting element according to claim 18, further comprising:
a second buffer layer disposed on one of principal surfaces of the first buffer layer and comprising GaN.

20. The nitride semiconductor light-emitting element according to claim 18, further comprising:
a third buffer layer disposed between the substrate and the first buffer layer and including Al.

21. The nitride semiconductor light-emitting element according to claim 17, wherein
a plurality of isolation trenches are formed on the substrate, and
the N-type cladding layer, the active layer, and the P-type cladding layer are stacked on the plurality of isolation trenches.

22. A nitride semiconductor light-emitting element comprising:
an N-type cladding layer stacked above a substrate that comprises GaN;
an N-side guide layer disposed above the N-type cladding layer;
an active layer disposed above the N-side guide layer and including a well layer and a barrier layer;
a P-type cladding layer disposed above the active layer;
a first buffer layer disposed between the substrate and the N-type cladding layer and including In; and
an intermediate buffer layer disposed between the substrate and the first buffer layer and including Al, wherein a band gap energy of the barrier layer is larger than an average band gap energy of the N-side guide layer,
a band gap energy of the N-type cladding layer is larger than the average band gap energy of the N-side guide layer,
a band gap energy of the N-side guide layer is larger in a lower end portion of the N-side guide layer than in an upper end portion of the N-side guide layer, and
the N-type cladding layer, the N-side guide layer, the barrier layer, and the P-type cladding layer each comprise a nitride semiconductor including Al.
